(19) United States
(12) Patent Application Publication
(10) Pub. No.: US 2004/0104454 A1
(43) Pub. Date: Jun. 3, 2004

(54) Semiconductor device and method of producing the same

(75) Inventors: Masaki Takaoka, Kyoto (JP); Noriyuki Shimoji, Kyoto (JP)

Correspondence Address: SHINJYU GLOBAL IP COUNSELORS, LLP, 1233 20TH STREET, NW, SUITE 700, WASHINGTON, DC, 20036-2680, US

(73) Assignee: ROHM CO., LTD., Kyoto (JP)

(21) Appl. No.: 10/605,585

(22) Filed: Oct. 10, 2003

(30) Foreign Application Priority Data
Oct. 10, 2002 (JP) 2002-297563
Oct. 11, 2002 (JP) 2002-298255

(51) Int. Cl. H01L 29/40

(52) U.S. Cl. 257/621; 257/698; 438/700

(57) ABSTRACT

A semiconductor device is disclosed which can be miniaturized and in which structures on a semiconductor substrate therein are difficult to delaminate, as well as a method of producing the same. The semiconductor device includes a semiconductor substrate main unit, and a thin portion that is thinner than the main unit and formed such that a recessed portion is formed in the semiconductor substrate and has at least one through hole formed therein. The thin portion is formed such that the etching rate of the thin portion is slower than the etching rate of the main unit. The thin portion provides a bridging structure between both sides of the recessed portion, and can mechanically and structurally strengthen the semiconductor device with respect to forces applied from the side surfaces of the main unit of the semiconductor substrate. Thus, structures such as wires, films, and semiconductor elements formed on the main unit and/or the thin portion of the semiconductor substrate or via the through holes will be difficult to detach from the semiconductor device.

### BACKGROUND OF INVENTION

1. Field of the Invention

The present invention relates to a semiconductor device.

2. Background Information

Micromachine technology has been proposed in the past that employs semiconductor materials such as silicon and the like. Devices that employ micromachine technology include sensors, semiconductor lasers, microactuators, fluid control devices such as micropumps and valves, and the like. With these types of devices, insulation film or metal patterns are generally used on the surface of the semiconductor substrate to form three dimensional structures. In addition, a metallic film (an inorganic film) is formed on the surface of the semiconductor substrate in a predetermined pattern, a resin film is then applied to the surface of the metallic film, and if the device is an ink jet head, a liquid chamber and ink flow paths that supply ink are then formed.

FIG. 24A shows an oblique cross-sectional view of a conventional semiconductor device having a through hole 17 therein, and FIG. 24B shows a plan view of this semiconductor device when viewed from the lower surface thereof. By forming the through hole 17 in a semiconductor substrate 10, a first opening 22 will be formed in the upper surface of the semiconductor substrate 10, and a second opening 24 will be formed in the lower surface of the semiconductor substrate 10. This type of through hole is generally formed by alkaline etching from the lower surface of the semiconductor substrate 10. When this occurs, in order to form the first opening 22 with the desired position and size in the upper surface of the semiconductor substrate 10, the second opening 24 in the lower surface of the semiconductor substrate is normally formed with a mask having an opening therein that is larger than the first opening 22. The thickness of the silicon or other semiconductor substrate that the through hole 17 is formed in, for example, is approximately 625 micrometers if the substrate is a 6 inch wafer, and deep etching is performed on the substrate. Because of that, there is no choice but to design the semiconductor device so that each through hole has a margin for the position and size of the first opening 22 in the upper surface of the semiconductor substrate. More specifically, even when one wants to employ a 6 inch silicon substrate and form the first opening 22 with a width of 20 micrometers in the surface thereof, it is estimated that a 100 micrometer space for each opening will be required during the production steps. Thus, because the first opening 22 in the upper surface of the semiconductor substrate 10 and the second opening 24 in the lower surface of the semiconductor substrate 10 will become larger, the semiconductor substrate 10 must become mechanically and structurally weak with respect to forces F (refer to the arrow in FIG. 24A) that are applied from both sides of the semiconductor substrate.

FIG. 24C shows a plan view of a semiconductor element formed on the semiconductor device shown in FIG. 24A, and FIG. 24D shows an oblique cross-sectional view of the semiconductor device shown in FIG. 24C that is taken along line D-D′ of FIG. 24C. A semiconductor element 30 that includes a gate electrode 32 that forms a portion of wiring 42, a source 34 and a drain 36 are formed on the semiconductor substrate 10. An interlayer insulation film 38 and wiring 40, 44 are sequentially formed on the semiconductor element 30. The wiring 40 extends from the lower surface of the semiconductor 10 to the upper surface thereof, is formed along a wall surface 19 of the through hole 17, and is connected to the source 34 of the semiconductor element 30 via a contact hole in the interlayer insulation film 38. The wiring 44 is connected to the drain 36 via the contact hole in the interlayer insulation film 38.

This type of semiconductor device can be used in a semiconductor device having semiconductor elements on both surfaces of the semiconductor substrate, or in a large scale LSI in which a plurality of semiconductor substrates are laminated together. However, because the semiconductor substrate 10 is a mechanically and structurally weak structure with respect to forces applied from both sides of the semiconductor substrate, there will be times when the semiconductor device 10 will flex and the structures formed on the semiconductor substrate will become detached therefrom. In addition, because the first opening 22 is formed widely in the upper surface of the semiconductor substrate 10, it will be difficult to form wiring at a high density and thus the semiconductor device will be unsuitable for miniaturization.

Furthermore, although the resin film (organic film) is formed on the upper surface of the metallic film (inorganic film) in conventional semiconductor devices, the adhesiveness between these two films is poor. In particular, when a pressure chamber and/or fluid paths are formed in the resin film, the forces generated therein by the discharge pressure of the fluid or the pressure of the fluid that flows in the fluid paths will attempt to delaminate the resin layer from the inorganic layer, and thus it will be easier for delamination to occur.

Accordingly, methods are employed that attempt to prevent this from occurring, such as increasing the adhesive surface area of the inorganic and resin films, using an organic film that has good adhesiveness with the inorganic film, or forming a buffer layer on the interface between these two films.

However, because the inorganic film is finely patterned, there will be many times in which it will be difficult to increase the adhesive surface area between the inorganic film and the organic film. In addition, depending on the type of device, there will be times in which the organic film must have a specific function, and thus in these situations it will be difficult to select a material for the organic film that has good adhesiveness with the inorganic film. Furthermore, forming a buffer layer on the interface between the two films will increase the number of steps in the production process and make the production process more complicated. In addition, the adhesive surface area with the buffer layer will be small because the inorganic film is finely patterned, and thus there will be little effect on the increase in adhesiveness due to the increase in the number of process steps.

It is an object of the present invention to provide a semiconductor device in which structures such as wiring and the like formed on the semiconductor device are difficult to delaminate therefrom, and a method of producing the same.

It is another object of the present invention to provide a semiconductor device that is mechanically and structurally strong with respect to forces applied from the sides of the semiconductor substrate, and a method of producing the same.

It is another object of the present invention to provide a semiconductor device that can be miniaturized, and a method of producing the same.

It is another object of the present invention to provide a semiconductor device in which the metallic film (inorganic film) and the resin film (organic film) are difficult to delaminate from each other, and a method of producing the same.

It is another object of the present invention to provide a semiconductor device in which the inorganic film and organic film can be made difficult to delaminate from each other without limiting the selection of the material for the organic film, and a method of producing the same.

It is another object of the present invention to provide a semiconductor device in which a buffer layer is not formed in the interface between the inorganic film and the organic film and both films are difficult to delaminate from each other, and a method of producing the same.

In view of the above, there exists a need for a method of producing a plate spring which overcomes the above mentioned problems in the prior art. This invention addresses this need in the prior art as well as other needs, which will become apparent to those skilled in the art from this disclosure.

### SUMMARY OF INVENTION

In order to achieve the aforementioned objects, a first aspect of the present invention is a semiconductor device having a semiconductor substrate main unit, and a thin portion that is thinner than the main unit and formed such that a recessed portion is formed in the semiconductor substrate, and the thin portion has at least one through hole formed therein. The thin portion is formed such that the etching rate of the thin portion is slower than the etching rate of the main unit.

The semiconductor device is formed with a semiconductor substrate main unit, and a thin portion that is thinner than the main unit such that a recessed portion is formed in the semiconductor substrate. The thin portion has at least one through hole formed therein. Flexion in the semiconductor device is reduced because the thin portion acts to bridge both sides of the recessed portion, and because the thin portion mechanically and structurally strengthens the semiconductor device with respect to forces applied from both side surfaces of the semiconductor substrate main unit. Thus, structures such as wires, films, and semiconductor elements formed on the semiconductor substrate main unit and/or the thin portion, or via the through holes, will be difficult to delaminate from the semiconductor device. In addition, because one or more through holes are formed in the thin portion, it will be easy to form wiring on the thin portion except the through holes, as well as form wiring that extends over to the main unit on both sides of the recessed portion. Furthermore, semiconductor devices can be formed on top of the thin portion, thereby making it possible to make a semiconductor device that is highly dense and miniaturized.

In a second aspect of the present invention, the thin portion and the main unit of the semiconductor device are unitarily formed.

The semiconductor device is unitarily formed by means of the semiconductor substrate main unit and the thin portion formed by eliminating a portion of the semiconductor substrate. Thus, the semiconductor device can be made mechanically and structurally stronger with respect to forces applied from the side surfaces of the semiconductor substrate main unit.

In a third aspect of the present invention, metal wiring is formed in the through holes of the semiconductor device.

By forming metal wiring in the through holes, wiring can be formed that extends from the upper surface of the semiconductor substrate to the lower surface of the semiconductor substrate, thereby making it possible to increase the density and miniaturization of the semiconductor device.

In a fourth aspect of the present invention, a resin film is formed on the thin portions of the semiconductor device.

Because the resin film is in contact with the thin portion that forms the recessed portion, the contact surface area between the semiconductor substrate and the resin film is increased. Thus, it will be difficult for the resin film to delaminate from the semiconductor device.

In a fifth aspect of the present invention, a dopant is infused in the thin portion of the semiconductor device.

By applying a dopant to the upper surface of the semiconductor substrate, the etching rate of the portions to which the dopant was applied can be slowed. Thus, by etching from the lower surface of the semiconductor substrate, a thin portion that is thinner than the semiconductor substrate main unit can be formed. The dopant may be one that can slow the etching rate, and is preferably a dopant such as boron, phosphorous, germanium, or the like.

In the first to fourth aspects of the present invention noted above, the thin portion is preferably formed by means of a selective oxide film. By forming a selective oxide film on the upper surface of the semiconductor substrate, the etching rate of the portion having the selective oxide film can be slowed. Thus, by etching from the lower surface of the semiconductor substrate, a thin portion that is thinner than the semiconductor substrate main unit can be formed. In addition, the selective oxide film can be formed by means of standard methods for forming LSI integrated circuits. Thus, because special processes are not necessary, the production process can be shortened and production costs can be reduced. In addition, a thin portion formed by means of a selective oxide film can be used as an interlayer insulation film having excellent electrical insulating properties.

In addition, the semiconductor device noted above is preferably formed by means of the following method of production. The semiconductor device is formed by means of a method of production that includes an etching stopper formation step that forms an etching stopper on a first surface of the semiconductor substrate, and a thin portion formation step that forms a recessed portion in the semiconductor substrate and a thin portion having at least one through hole formed therein by etching the semiconductor substrate from a second surface that is opposite the first surface of the semiconductor substrate such that the etching stopper remains.

In this method of production, the etching stopper is formed such that the etching rate can be reduced by means of a semiconductor substrate having a dopant infused therein, a selective oxide film, or the like. When the semiconductor substrate having an etching stopper on the first surface thereof is etched from the second surface thereof, a recessed portion is formed thereby and the etching stopper that remains is a thin portions interposed by the main unit of the semiconductor substrate. The thin portion includes portions in which the etching stopper is not formed, and at least one through hole is formed in the thin portion by etching these portions. A semiconductor device obtained in this manner will have a reduced amount of flexion therein because the thin portion bridges both sides of the recessed portion, and because the thin portion mechanically and structurally strengthens the semiconductor device with respect to forces applied from both side surfaces of the semiconductor substrate main unit. Thus, structures such as wires, films, and semiconductor elements formed on the semiconductor substrate main unit and/or the thin portion, or via the through holes, will be difficult to delaminate from the semiconductor device. In addition, because one or more through holes are formed in the thin portion, it will be easy to form wiring on the thin portion except the through holes, as well as form wiring that extends over to the main unit on both sides of the recessed portion. Furthermore, semiconductor devices can be formed on top of the thin portion, thereby making it possible to make a semiconductor device that is highly dense and miniaturized.

In a sixth aspect of the present invention, the semiconductor device is employed in a micromachine, and includes a semiconductor substrate, attachment organic films, an inorganic film, and an organic film. The attachment organic film is formed on at least a portion of the surface of the semiconductor substrate. The inorganic film is formed on a surface of the semiconductor substrate that is opposite the surface in which the attachment organic film is formed, and includes a through hole which the attachment organic film cannot pass through. The organic film is provided on the surface of the inorganic film such that the inorganic film is interposed between the attachment organic film and the organic film, and is unitarily formed with the attachment organic film via the through hole.

In this device, the attachment organic film, the inorganic film and the organic film are sequentially formed on the surface of the semiconductor substrate. When this occurs, the attachment organic film and the organic film are linked together and unitarily formed via the through hole formed in the inorganic film, and the attachment organic film cannot pass through the through hole in the inorganic film.

Thus, even if a force is applied to the organic film that would delaminate it from the inorganic film, the attachment organic film unitarily formed with the organic film will mechanically engage with the inorganic film and make it difficult for the organic film to delaminate from the inorganic film. Because of this, it will not be necessary to increase the adhesive surface area between the organic film and the inorganic film, and there will be no limitations when selecting the materials for the organic film. Furthermore, there will be no need to form a buffer layer on the interface between the inorganic film and the organic film.

In a seventh aspect of the present invention, localized recessed portions are formed in the surface of the semiconductor substrate, and the attachment organic films are formed by filling the organic film into the localized recessed portions via the through holes.

This allows the attachment organic films to be easily formed. In addition, because the attachment organic films are only filled into the localized recessed portions, the adhesiveness between the semiconductor substrate and the inorganic film can be improved in situations in which the inorganic film adheres to the semiconductor substrate other than at the recessed portions and the semiconductor substrate is formed with an inorganic material.

In an eighth aspect of the present invention, the attachment organic films are formed from portions of the organic film formed on the surface of the semiconductor substrate.

Depending on the type of device, the organic film may be formed between the semiconductor substrate and the inorganic film. Here, portions of the organic film on the surface of the semiconductor substrate can be made into the attachment organic films by linking and unitarily forming the organic film formed on the surface of the inorganic film with the organic film formed on the surface of the semiconductor substrate via the through holes provided in the inorganic film. Thus, the organic film formed on the surface of the inorganic film can be made more difficult to delaminate from the inorganic film.

In a ninth aspect of the present invention, a functional component that generates pressure in a direction that would delaminate the organic film from the inorganic film is formed in the organic film.

For example, in a situation in which a fluid chamber or ink fluid paths for an ink jet head are formed in the organic film, the ink discharge pressure and/or the pressure generated when the ink flows through the fluid paths is applied to the organic film and these pressures attempt to delaminate the organic film from the inorganic film. However, although the organic film is formed on the surface of the inorganic film, the organic film will be difficult to delaminate from the inorganic film because the organic film is linked and unitarily formed with the attachment organic films formed on the side opposite the main surface of the inorganic film.

In a tenth aspect of the present invention, the inorganic film is a metallic film that is applied in a predetermined pattern.

When the inorganic film is formed with a metallic film that has been particularly finely patterned, it will be difficult to make it properly adhere to an organic film formed on the surface thereof. However, like noted above, although the organic film is formed on the surface of the inorganic film, the organic film will be difficult to delaminate from the inorganic film because the organic film is linked and unitarily formed with the attachment organic films formed on the side opposite the main surface of the inorganic film.

In an eleventh aspect of the present invention, the semiconductor device is employed in a micromachine, and includes a semiconductor substrate, an inorganic film, and an organic film. The inorganic film is formed on one of the main surfaces of the semiconductor substrate. The organic film is formed on the surface of the inorganic film such that the inorganic film is interposed between the organic film and the semiconductor substrate. Then, a through hole is formed in the inorganic film such that the through holes pass from the main surface of the inorganic film on the organic film side through to an opposite side of the inorganic film, attachment recessed portions are formed in the semiconductor substrate such that at least one portion of each of the outer peripheries thereof extends outward beyond the through holes, and the organic film is filled into the through holes and the attachment recessed portions.

Here, like noted above, although the organic film is formed on the surface of the inorganic film, the organic film will be difficult to delaminate from the inorganic film because the organic film is linked and unitarily formed with the attachment organic films formed on the side opposite the main surface of the inorganic film. In addition, because the attachment organic films are only filled into the recessed portions, the adhesiveness between the semiconductor substrate and the inorganic film can be improved in situations in which the inorganic film adheres to the semiconductor substrate other than at the recessed portions and the semiconductor substrate is formed with an inorganic material.

In a twelfth aspect of the present invention, the semiconductor device is employed in a micromachine, and includes a semiconductor substrate, a first organic film, an inorganic film, and a second organic film. The first organic film is formed on a main surface of the semiconductor substrate. The inorganic film is formed on a surface of the first organic film that is opposite the surface of the first organic film that is adjacent to the semiconductor substrate. The second organic film is formed on the surface of the inorganic film such that the inorganic film is interposed between the first organic film and the second organic film. Then, a through hole is formed in the inorganic film such that the through hole passes from the main surface of the inorganic film on the second organic film side through to an opposite side of the inorganic film, and the second organic film and the first organic film are linked together and unitarily formed via the through hole.

Here, like noted above, although the second organic film is formed on the surface of the inorganic film, the second organic film will be difficult to delaminate from the inorganic film because the second organic film is linked and unitarily formed with the first organic film formed on the side opposite the main surface of the inorganic film. In addition, depending on the type of device, although there will be times in which the first organic film will be formed between the semiconductor substrate and the inorganic film, portions of the first organic film on the surface of the semiconductor substrate can be made into attachment organic films by linking and unitarily forming the first organic film formed on the surface of the semiconductor substrate with the second organic film formed on the surface of the inorganic film via the through holes provided in the inorganic film.

These and other objects, features, aspects and advantages of the present invention will become apparent to those skilled in the art from the following detailed description, which, taken in conjunction with the annexed drawings, discloses a preferred embodiment of the present invention.

### BRIEF DESCRIPTION OF DRAWINGS

Referring now to the attached drawings which form a part of this original disclosure:

FIG. 1A shows an oblique cross-sectional view of a semiconductor device according to a first embodiment of the present invention, and FIG. 1B shows a plan view of the lower surface of the semiconductor substrate of the semiconductor device shown in FIG. 1A;

FIG. 2 shows a cross-sectional view of steps in a first method of producing the semiconductor device shown in FIG. 1;

FIG. 3 shows a graph that describes the relationship between dopant concentration and the etching rate of silicon;

FIG. 4 shows a cross-sectional view of another semiconductor device produced by the first production method depicted in FIG. 2;

FIG. 5 shows a cross-sectional view of steps in a second method of producing the semiconductor device shown in FIG. 1;

FIG. 6 shows a cross-sectional view of another semiconductor device produced by the second production method shown in FIG. 5;

FIG. 7 shows an oblique cross-sectional view of a semiconductor device in which the semiconductor device according to first embodiment is employed;

FIG. 8 is an oblique cross-sectional view showing steps in the production of the semiconductor device depicted in FIG. 7;

FIG. 9 is an oblique cross-sectional view of a semiconductor device in which the semiconductor device depicted in FIG. 7 is laminated thereon;

FIG. 10 is an oblique cross-sectional view of a semiconductor device in which semiconductor elements are formed on the upper and lower surfaces of the semiconductor substrate;

FIG. 11 shows an oblique cross-sectional view of a semiconductor device in which the semiconductor device depicted in FIG. 10 is laminated thereon;

FIG. 12 is a cross-sectional view of a micropump which employs the semiconductor device according to the first embodiment of the present invention;

FIG. 13A is an enlarged view of a recessed portion formed in a semiconductor substrate employed in the micropump depicted in FIG. 12, FIG. 13B is a plan view of the micropump taken along line A-A′ in FIG. 12; and FIG. 13C is an enlarged view of a valve used in the micropump depicted in FIG. 12;

FIG. 14 shows a plan view of the micropump depicted in FIG. 12 showing L-shaped or step shaped pressure chambers formed therein;

FIG. 15 shows cross-sectional views taken along line B-B′ of FIG. 13B of steps in the production of the essential elements of the micropump depicted in FIG. 12;

FIG. 16 shows cross-sectional views taken along line C-C′ of FIG. 13B of steps in the production of the essential elements of the micropump depicted in FIG. 12;

FIG. 17 shows a cross-sectional view of a semiconductor device for a micropump according to a second embodiment of the present invention;

FIG. 18 shows steps in the production of the semiconductor device depicted in FIG. 17;

FIG. 19 shows a cross-sectional view of a semiconductor device for a micropump according to a third embodiment of the present invention;

FIG. 20 shows steps in the production of the semiconductor device depicted in FIG. 19;

FIG. 21 shows a cross-sectional view of a semiconductor device for a micropump according to another embodiment of the present invention;

FIG. 22A shows a cross-sectional view of a micropump which employs the semiconductor device depicted in FIG. 17, and FIG. 22B shows an enlarged view of a valve used in the micropump depicted in FIG. 22A;

FIG. 23 shows steps in the production of the essential elements of the micropump depicted in FIG. 22; and

FIG. 24A shows an oblique cross-sectional view of a conventional semiconductor device having a through holes formed therein, FIG. 24B shows a plan view of the lower surface of the semiconductor substrate of the semiconductor device depicted in FIG. 24A, FIG. 24C shows a plan view of a semiconductor element formed on the semiconductor device depicted in FIG. 24A, and FIG. 24D shows an oblique cross-sectional view of the semiconductor element depicted in FIG. 24C taken along line D-D′ of FIG. 24C.

### DETAILED DESCRIPTION

1. First Embodiment

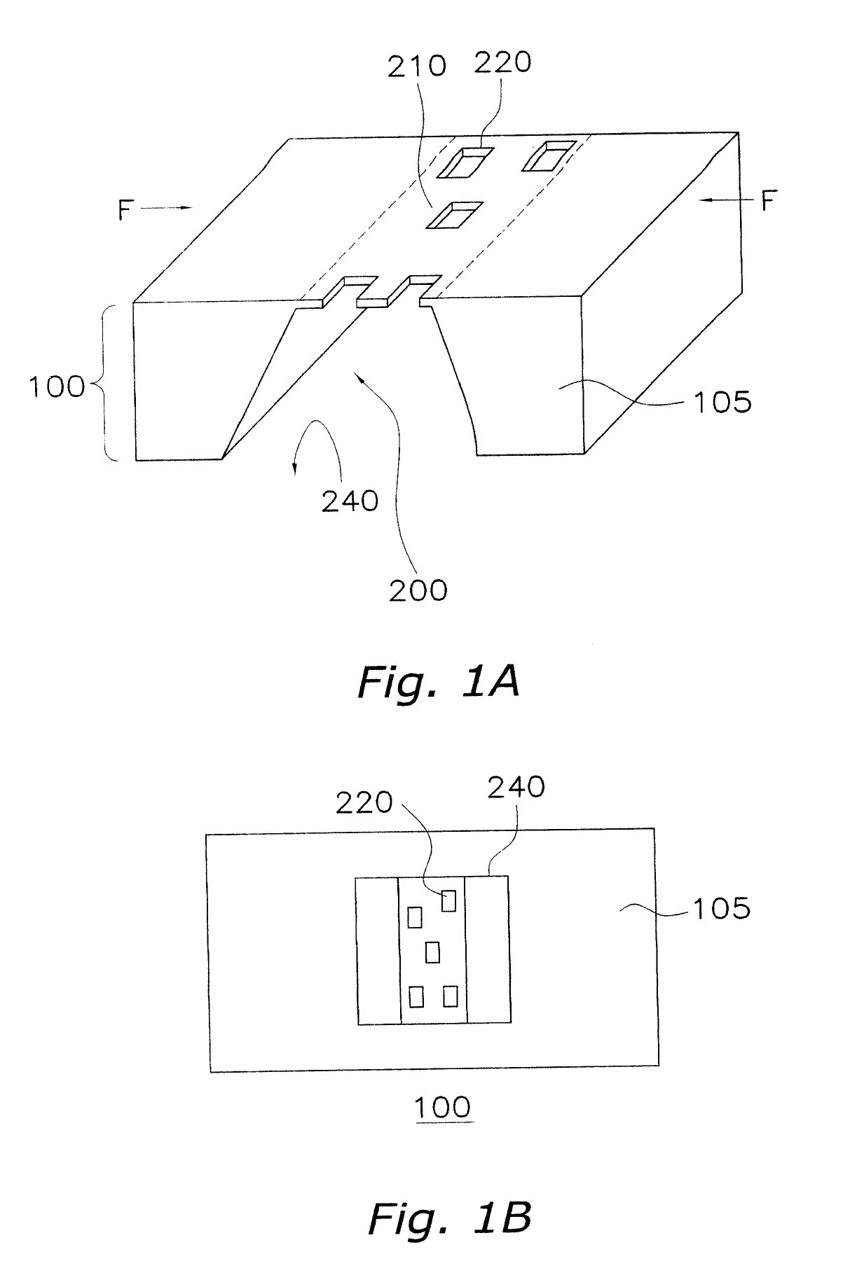

A first embodiment of the present invention will be described below. FIG. 1A shows an oblique cross-sectional view of a semiconductor device according to the first embodiment of the present invention, and FIG. 1B shows a plan view of the semiconductor device when viewed from the lower surface of the semiconductor substrate.

A semiconductor substrate 100 of the semiconductor device includes a semiconductor substrate main unit 105 and a thin portion 210 on the upper surface side of the semiconductor substrate 100. The thin portion 210 is positioned between the semiconductor substrate main unit 105, and is thinner than the semiconductor substrate main unit 105. In addition, a recessed portion 200 and an opening 240 in the lower surface of the semiconductor substrate 100 are formed by means of the thin portion 210 and the semiconductor substrate main unit 105. At least one through hole 220 is formed in the thin portion 210. The thin portion 210 can be formed by dopant infusion or a selective oxide film.

Thus, because the thin portion 210 is formed between the semiconductor substrate main unit 105, the thin portion 210 acts as a bridge across the semiconductor substrate main unit 105. Therefore, the semiconductor device can be made mechanically and structurally stronger with respect to forces F (depicted by arrows in FIG. 1A) applied from both sides of the semiconductor substrate. For example, because one or more through holes 220 are formed in the thin portion 210, it will be easy to form wiring on the thin portion 210 except the through holes 220, and also form wiring that extends over to both sides of the recessed portion 200 in the main unit 105. Furthermore, semiconductor elements can be formed on top of the thin portion 210, thereby making it possible to make a semiconductor device that is highly dense and miniaturized. In addition, a thin portion formed by means of a selective oxide film can be used as an interlayer insulation film having excellent electrical insulating properties. Furthermore, flexion of the semiconductor device will be reduced because the semiconductor device is mechanically and structurally strengthened by the thin portion 210. Thus, structures such as wires, films, and semiconductor elements formed on the main unit 105 and/or the thin portion 210 of the semiconductor substrate or via the through holes 220 will be difficult to delaminate from the semiconductor device.

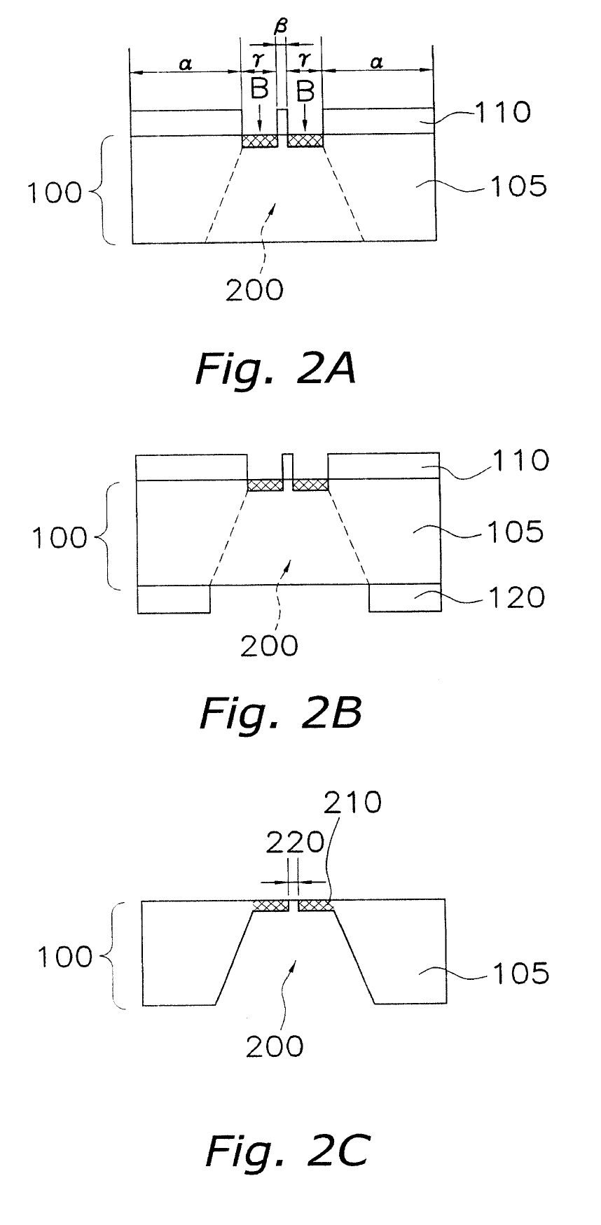

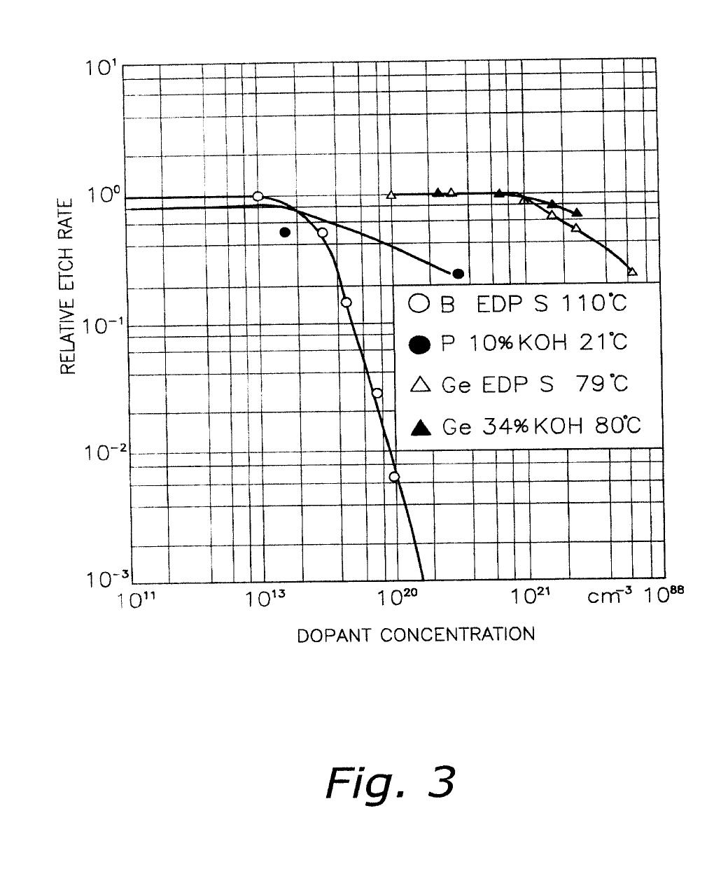

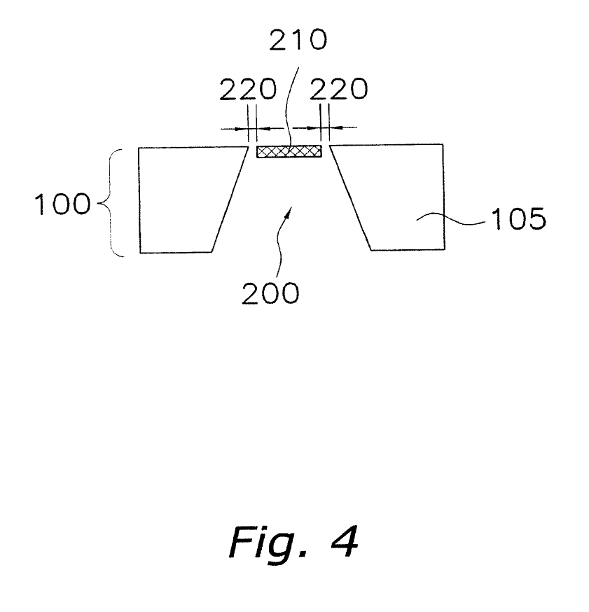

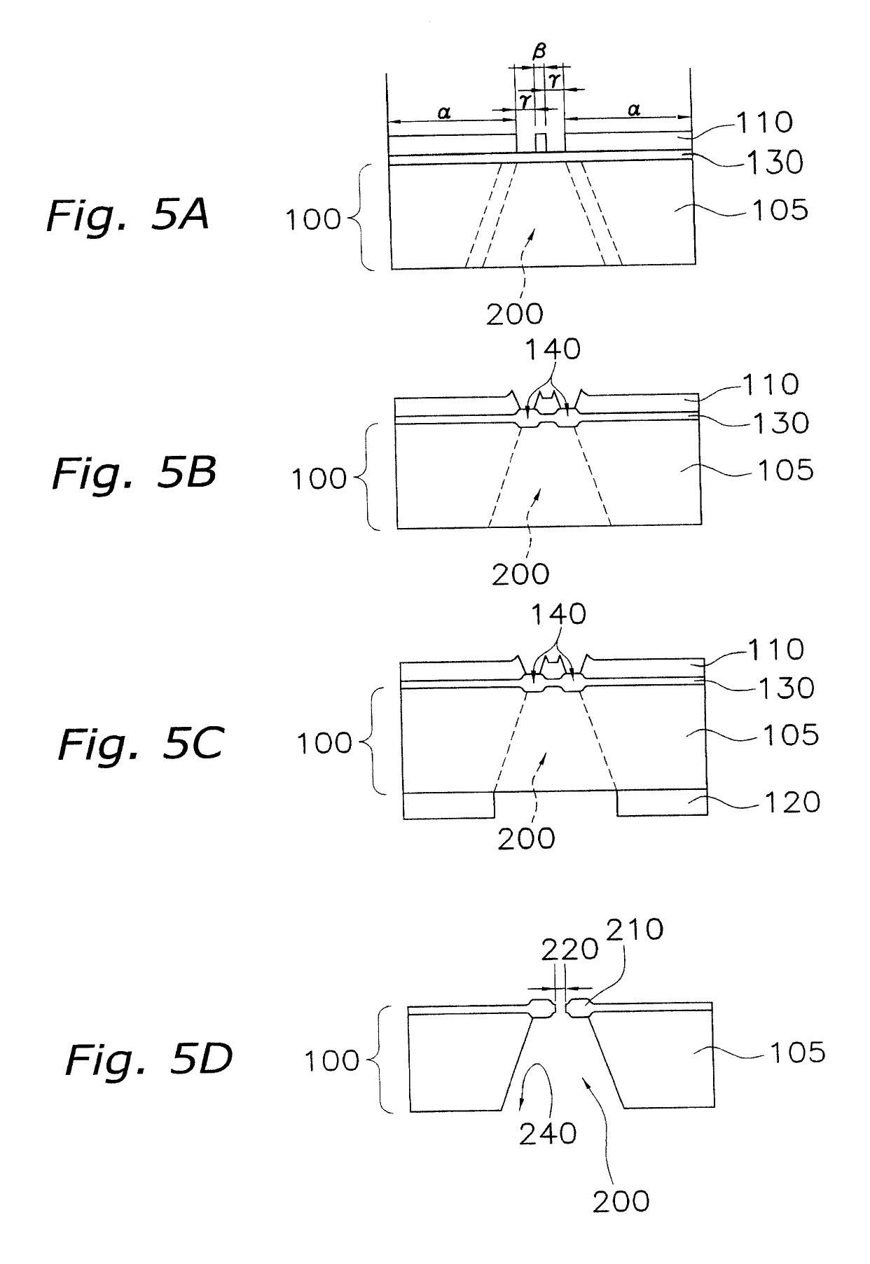

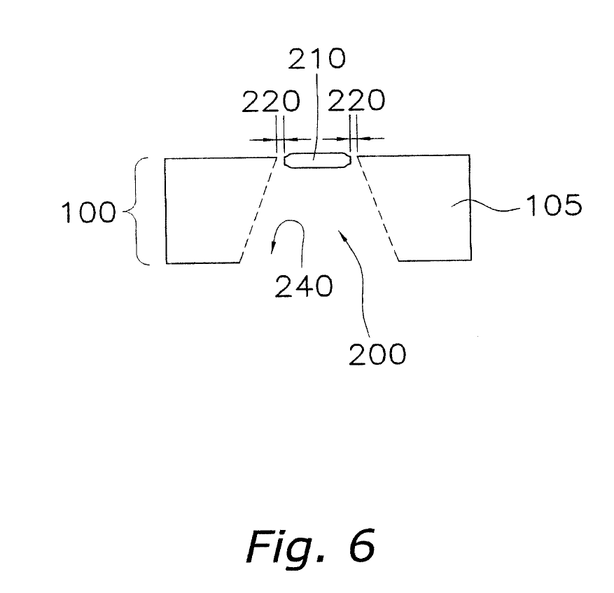

A method of producing this semiconductor device will now be described. Two methods of production will be used as examples, a first production method in which the thin portion is formed by infusing a dopant such as boron or the like, and a second production method in which the thin portion is formed by means of a selective oxide film. FIGS. 2A-C are cross-sectional views of the first production method for the semiconductor substrate shown in FIG. 1A, FIG. 3 shows the relationship between dopant concentration and the silicon etching rate, FIG. 4 is a cross-sectional view of another semiconductor device produced by the first production method, FIGS. 5A-D are cross-sectional views of the second production method for the semiconductor substrate shown in FIG. 1A, and FIG. 6 is a cross-sectional view of another semiconductor device produced by the second production method.

FIGS. 2A-C will be employed to describe the first production method. First, a mask 110 such as a resist or the like is formed on portions # of the semiconductor substrate 100 that will be formed into the main unit 105 and a portion # of the semiconductor substrate 100 in which the through hole 220 will be formed. Then, a dopant such as boron (B) or the like is infused in the upper surface of the semiconductor substrate 100 through openings # in the mask 110 (refer to FIG. 2A). The dopant may be one that can slow the etching rate of silicon, and is preferably boron, phosphorous, germanium, or the like. The dopant is infused at a density such that the etching rate of the semiconductor substrate will be slower than that of the portions of the semiconductor substrate having little or no dopant infused therein. FIG. 3 shows that the etching rate can be satisfactorily slowed when a silicon substrate is infused with boron at a density of 1×10¹⁹ pcs/cm³ or greater.

Next, a mask 120 for etching the bottom surface of a silicon oxide layer or the like is formed on the lower surface of the semiconductor substrate 100, and has an opening therein in a position opposite to the portions # in which dopant was infused (refer to FIG. 2B).

The mask 120 is used to form the thin portion 210 having the through hole 220 therein by anisotropically etching the bottom surface of the semiconductor substrate 100. When this etching occurs, the recessed portion 200 will be formed, and will be surrounded by the main unit 105 and the semiconductor substrate thin portion 210. When this etching occurs, the etching rate of the # portions of the semiconductor substrate 100 will be slower than that of the other portions of the semiconductor substrate 100 because the dopant is infused in the # portions. Because of that, the portions # in which dopant was infused will remain and not be etched, thus forming the thin portion 210. On the other hand, etching will proceed up to the upper surface of the portion # of the semiconductor substrate in which the dopant is not infused, thus forming the through hole 220. In the last step, the masks 110, 120 are removed (refer to FIG. 2C). An alkaline etching process is preferably used to conduct the etching from the bottom surface of the semiconductor substrate 100. Alkaline etching has a good ability to control the dimensions of the opening because the etching can be conducted by means of an SiO₂ or Si₃N₄ mask, and because there is little spread in the horizontal direction during the anisotropic etching process.

Thus, the through hole 220 can be formed in an accurate position by controlling the places in which dopant is infused.

As noted above, the thin portion 210 was formed in the # position and the through hole 220 was formed in the # position. However, through holes 220 and the thin portion 210 may be formed as shown in FIG. 4.

Next, FIGS. 5A-D will be employed to describe the second production method. First, a silicon oxide film 130 is formed on the semiconductor substrate 100 by oxidizing the semiconductor substrate 100. Then, a mask 110 such as a silicon nitride layer or the like is formed on portions # of the silicon oxide film 130 that will form the main unit 105 and a portion # of the silicon oxide film 130 in which the through hole 220 will be formed (refer to FIG. 5A).

Next, selective oxide films (LOCOS) 140 will be formed in openings # in the mask 110 by thermally oxidizing the semiconductor substrate 100 (refer to FIG. 5B).

Next, a mask 120 for etching the bottom surface of a silicon oxide layer or the like is formed on the lower surface of the semiconductor substrate 100, and has an opening therein in a position opposite to the portions in which the selective oxide films 140 were formed (refer to FIG. 5C).

The mask 120 is used to form the thin portion 210 (the selective oxide films 140) and the through hole 220 by anisotropically etching the bottom surface of the semiconductor substrate 100 with an etching process that is preferably an alkaline etching process. When this etching occurs, the etching rate of # portions will be slower than that of the portions that do not have the selective oxide films 140 formed thereon because the selective oxide films 140 are formed on the # portions of the semiconductor substrate 100. Because of that, the portions # in which the selective oxide films were formed will remain and not be etched, thus forming the thin portion 210 (selective oxide films 140). On the other hand, etching will proceed up to the upper surface of the portion # of the semiconductor substrate in which the selective oxide films are not formed, thus forming the through hole 220 in the thin portion 210. When this occurs, the recessed portion 200 is formed, and is surrounded by the semiconductor substrate main unit 105 and the thin portion 210. In the last step, the masks 110, 120 are removed (refer to FIG. 5D).

The selective oxide films 140 can be formed by means of standard methods for forming LSI integrated circuits. Thus, because special processes are not necessary, the production process can be shortened and production costs can be reduced. In addition, the through hole 220 can be formed in an accurate position by controlling the places in which selective oxide films are formed.

As noted above, the thin portion 210 was formed in the # position and the through hole 220 was formed in the # position. However, through holes 220 and the thin portion 210 may be formed as shown in FIG. 6.

### EXAMPLE 1

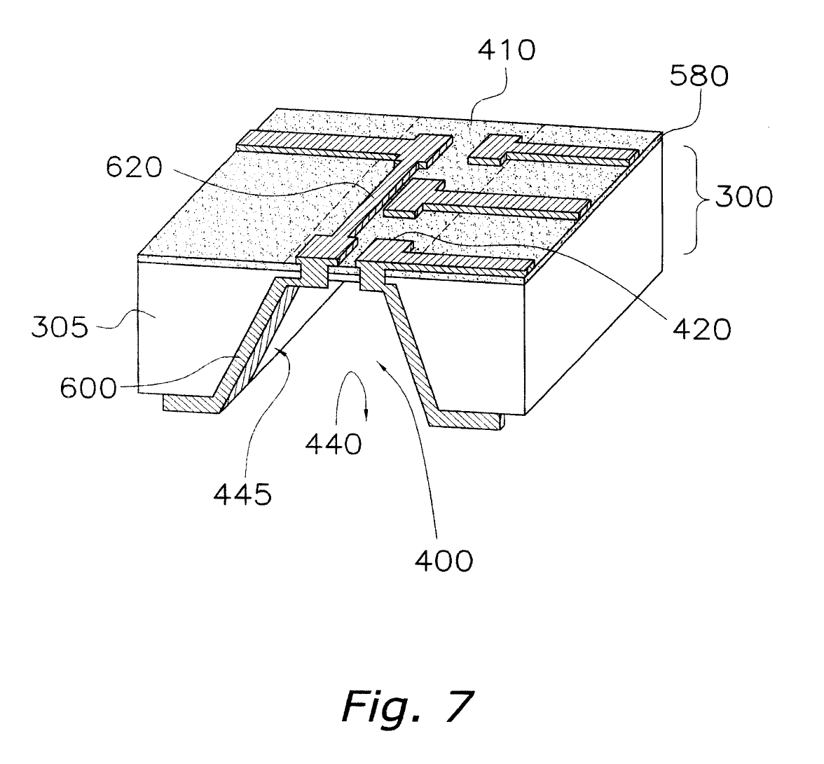

FIG. 7 is an example of the application of the basic structure of the first embodiment to a semiconductor device having microwiring. A semiconductor substrate 300 of this semiconductor device includes a semiconductor substrate main unit 305, a thin portion 410 on the upper surface side of the semiconductor substrate 300, an interlayer insulation film 580 formed on the semiconductor substrate 300, and wiring 600, 620. The thin portion 410 is positioned between the semiconductor substrate main unit 305, and is thinner than the semiconductor substrate main unit 305. Through holes 420 are formed in the thin portion 410. In addition, a recessed portion 400 and an opening 440 on the lower surface of the semiconductor substrate 300 are formed by means of the thin portion 410 and the semiconductor substrate main unit 305. The wiring 600 connects the upper surface and the lower surface of the semiconductor substrate 300, and is formed along a wall surface 445 of the recessed portion 400 via the through holes 420. In addition, the wiring 620 is formed on the interlayer insulation film 580 on top of the thin portion 410. Thus, the mechanical and structural strength of the semiconductor device can be increased by means of the thin portion 410, and the semiconductor device can be miniaturized by forming wiring at a high density on the thin portion 410. In addition, flexion of the semiconductor device will be reduced because the semiconductor device is mechanically and structurally strengthened by the thin portion 410. Thus, structures such as the wires 600, 620, the interlayer insulation film 580, and semiconductor elements formed on the semiconductor substrate main unit 305 and/or the thin portion 410 or via the through holes 420 will be difficult to delaminate from the semiconductor device.

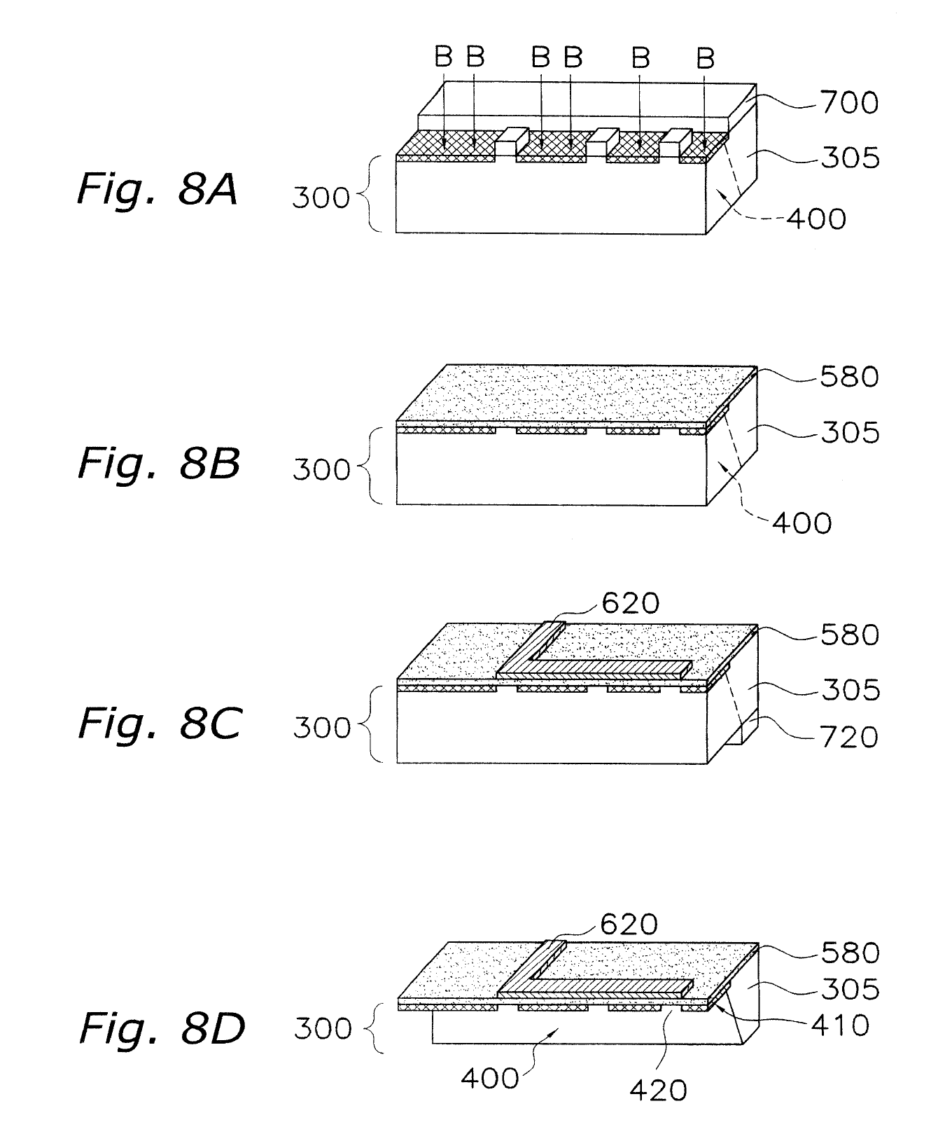

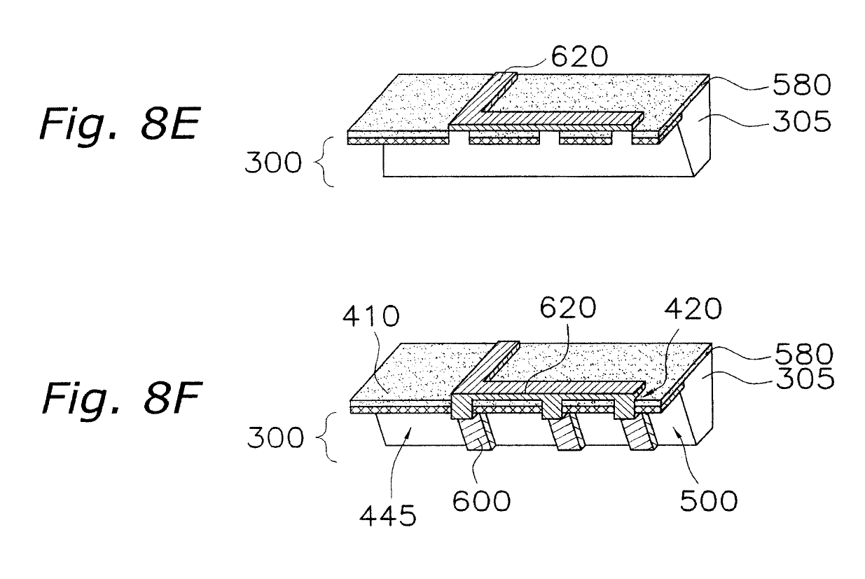

FIGS. 8A-F show steps in the production of the semiconductor device of FIG. 7. FIG. 8F is an oblique cross-sectional view of the semiconductor device. The wiring 600 is formed along the wall surface 445 of the recessed portion 400 via the through holes 420, and the wiring 620 is formed on the interlayer insulation film 580 on the thin portion 410 and on the semiconductor substrate main unit 305.

First, a mask 700 such as a resist or the like having openings therein is formed on the semiconductor substrate 300. Then, a dopant such as boron (B) or the like is infused in the upper surface of the semiconductor substrate 300 from the openings in the mask 700 (refer to FIG. 8A). The position in which the openings in the mask 700 are formed are the portions that form the thin portion 410. The type and density of dopant to be infused therein is as noted above.

Next, the mask 700 is removed, and the interlayer insulation film 580 is formed on the semiconductor substrate 300 (refer to FIG. 8B).

The wiring 620 is formed on the interlayer insulation film 580, and a lower surface etching mask 720 is formed on the lower surface of the semiconductor substrate 300. The lower surface etching mask 720 is a silicon oxide film or the like that has an opening in a position that is opposite the portions in which the dopant was infused (refer to FIG. 8C).

The lower surface etching mask 720 is used to anisotropically etch the bottom surface of the semiconductor substrate 300 with an etching process that is preferably an alkaline etching process, and the portions of the semiconductor substrate 300 in which the dopant such as boron (B) or the like was not infused is removed thereby. Thus, the thin portion 410, the through holes 420, and the recessed portion 400 are formed thereby. The mask 720 is then removed (refer to FIG. 8D).

Next, the interlayer insulation film 580 exposed by the through holes 420 is removed up to the point in which the surface of the wiring 620 is exposed by dry etching from the lower surface of the semiconductor substrate 300 (refer to FIG. 8E).

The wiring 600 is formed along the wall surface 445 of the recessed portion 400 via the through holes 420, and the wiring 620 is then connected with the wiring 600 (refer to FIG. 8F). A mask for forming the wiring 600 is formed by using a method that is capable of forming a mask on a non-planar surface. For example, this can be performed by spraying and atomizing resist particles in a pressurized gas. In order to optimize the drying of the resist particles adhered to the semiconductor substrate and the speed of flattening due to the melting of the particles, the distance between the semiconductor substrate and the spraying device, the temperature of the semiconductor device, and the like, will be optimized to conduct resist formation.

### EXAMPLE 2

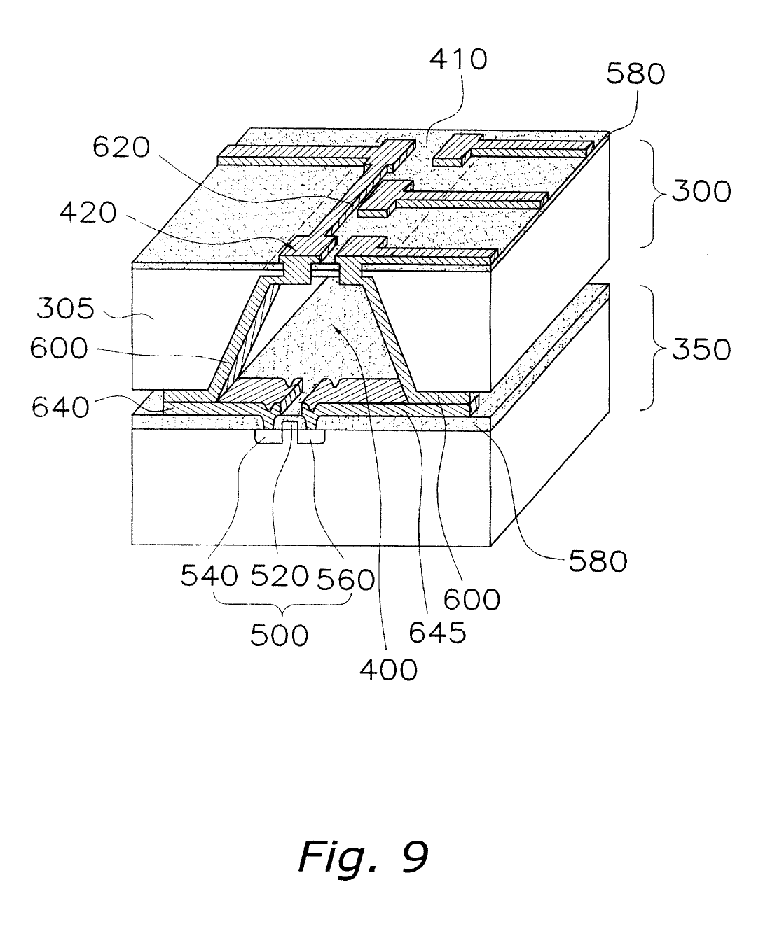

FIG. 9 is an example in which the semiconductor device of FIG. 7 is laminated. As shown in FIG. 9, a semiconductor element 500 that includes a gate electrode 520, a source 540, and a drain 560 is formed on a semiconductor substrate 350. The interlayer insulation film 580 and wiring 640, 645 are sequentially formed on the semiconductor element 500. The wiring 640, 645 are respectively connected to the source 540 and drain 560 via a contact hole in the interlayer insulation film 580. The semiconductor substrate 300 is laminated onto the upper portion of the semiconductor substrate 350 to form a unitary semiconductor device. The wiring structure on the upper portion of the semiconductor substrate 300 is identical to that shown in FIG. 7. Here, the electrical connection between the upper portion of the semiconductor substrate 300 and the lower portion of the semiconductor substrate 350 is carried out by connecting the wiring 640, 645 on the lower portion of the semiconductor substrate 350 with the wiring 600 on the upper portion of the semiconductor substrate 300. A two layer laminated structure was described above, however a plurality of semiconductor substrates may also be laminated to each other. Due to the above structure, the semiconductor device will be mechanically and structurally strengthened by the thin portion 410, and flexion of the semiconductor device will be reduced. As a result, structures such as the wiring, the films, and the semiconductor elements on the semiconductor substrate will be difficult to delaminate from the semiconductor device. In addition, the semiconductor device can be miniaturized by forming wiring at a high density on the thin portion 410, and a multi-layered semiconductor device can thereby be produced.

### EXAMPLE 3

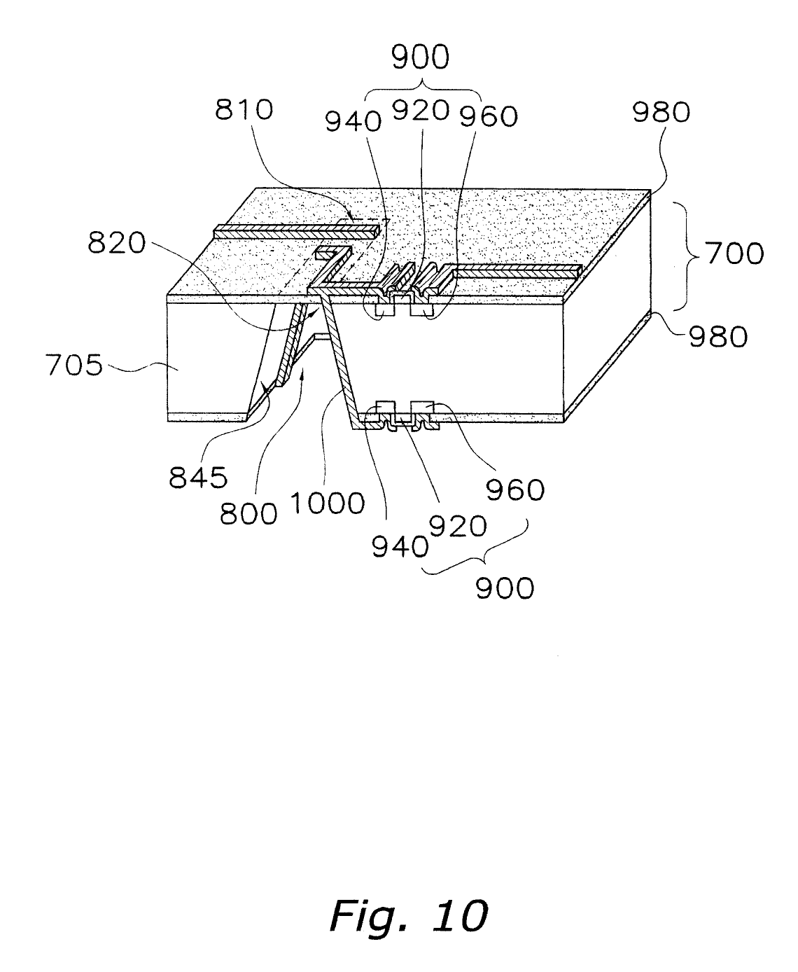

FIG. 10 shows an example of a semiconductor device in which semiconductor elements are formed on the upper and lower surfaces of the semiconductor substrate. Semiconductor elements 900 that each include a gate electrode 920, a source 940 and a drain 960 are respectively formed on the upper and lower surfaces of a semiconductor substrate 700. An interlayer insulation film 980 and wiring 1000 are sequentially formed on each of the semiconductor elements 900. The semiconductor elements 900 on the upper and lower surfaces of the semiconductor substrate 700 are connected to each other by means of the wiring 1000. The wiring 1000 is formed on the thin portion 810 and the semiconductor substrate main unit 705, and is formed along a wall surface 845 of a recessed portion 800 via a through hole 820. Due to the above structure, the semiconductor device will be mechanically and structurally strengthened by the thin portion 810, and flexion of the semiconductor device will be reduced. As a result, structures such as the wiring on the semiconductor substrate, the films, and the semiconductor elements will be difficult to detach from the semiconductor device, and the semiconductor device can be miniaturized by forming wiring and the semiconductor elements 900 at a high density on the thin portion 810. In addition, the density of the semiconductor device can be further increased because the semiconductor elements 900 are formed on both the upper surface and the lower surface of the semiconductor substrate 700 and wired together.

### EXAMPLE 4

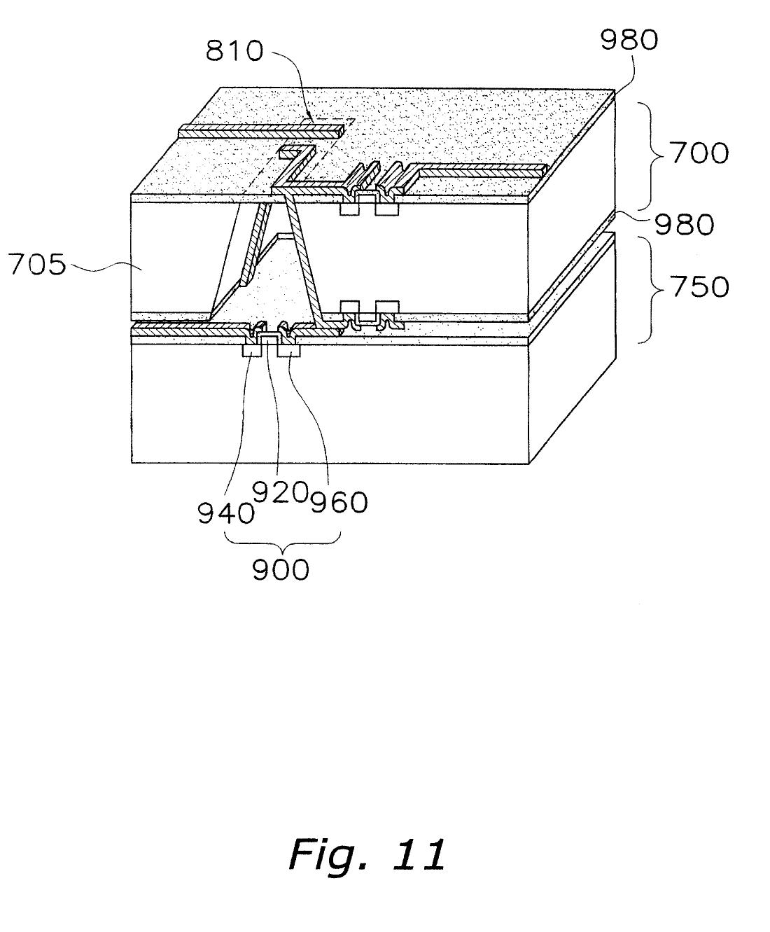

FIG. 11 is an example in which the semiconductor device of FIG. 10 is laminated. The semiconductor device of FIG. 10 can also be laminated onto another semiconductor substrate 750 on which another semiconductor element 900 is formed, thereby making it possible to further increase the density and number of layers of the semiconductor device. A two layer laminated structure is described here, however a plurality of semiconductor devices may also be laminated to each other.

### EXAMPLE 5

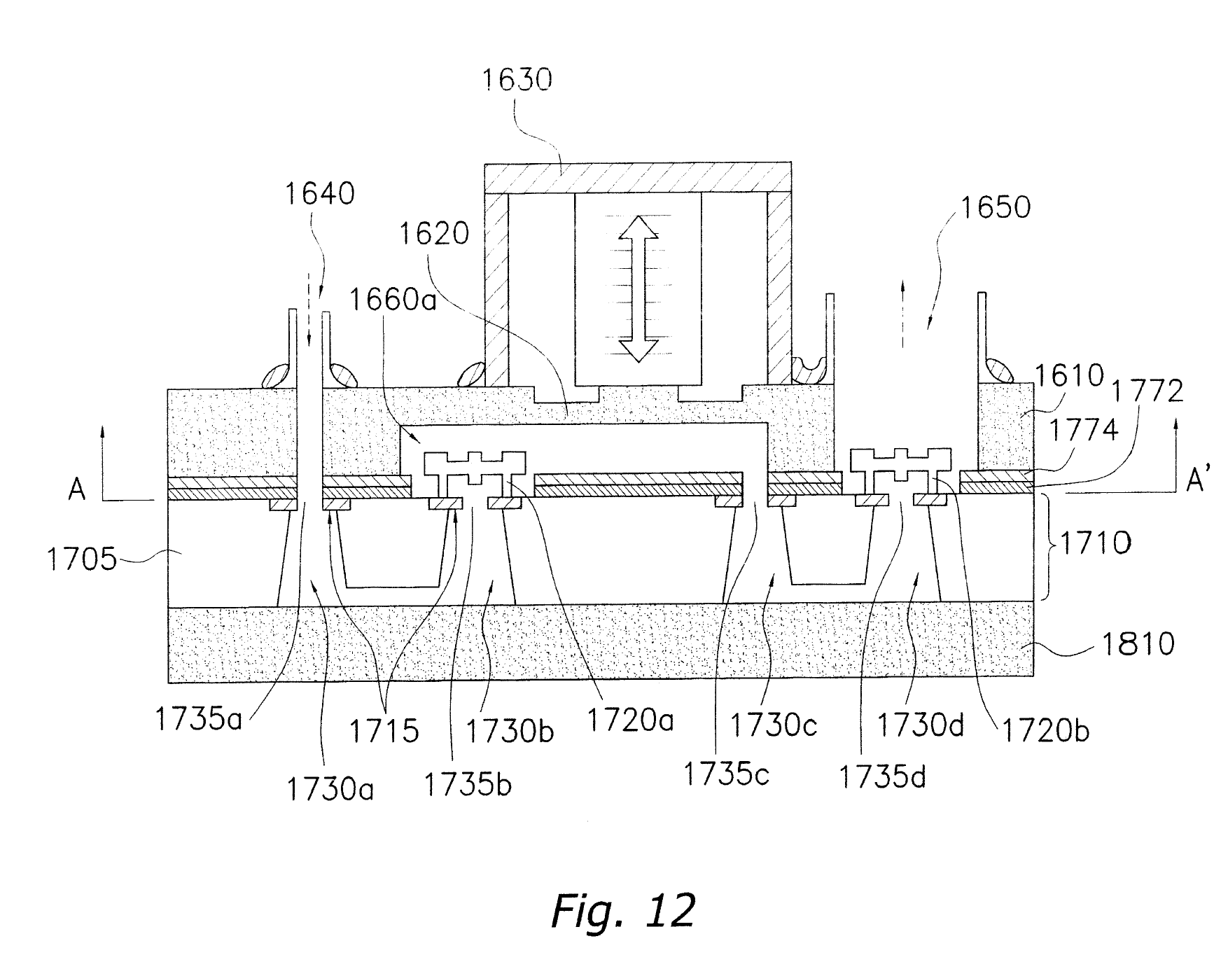

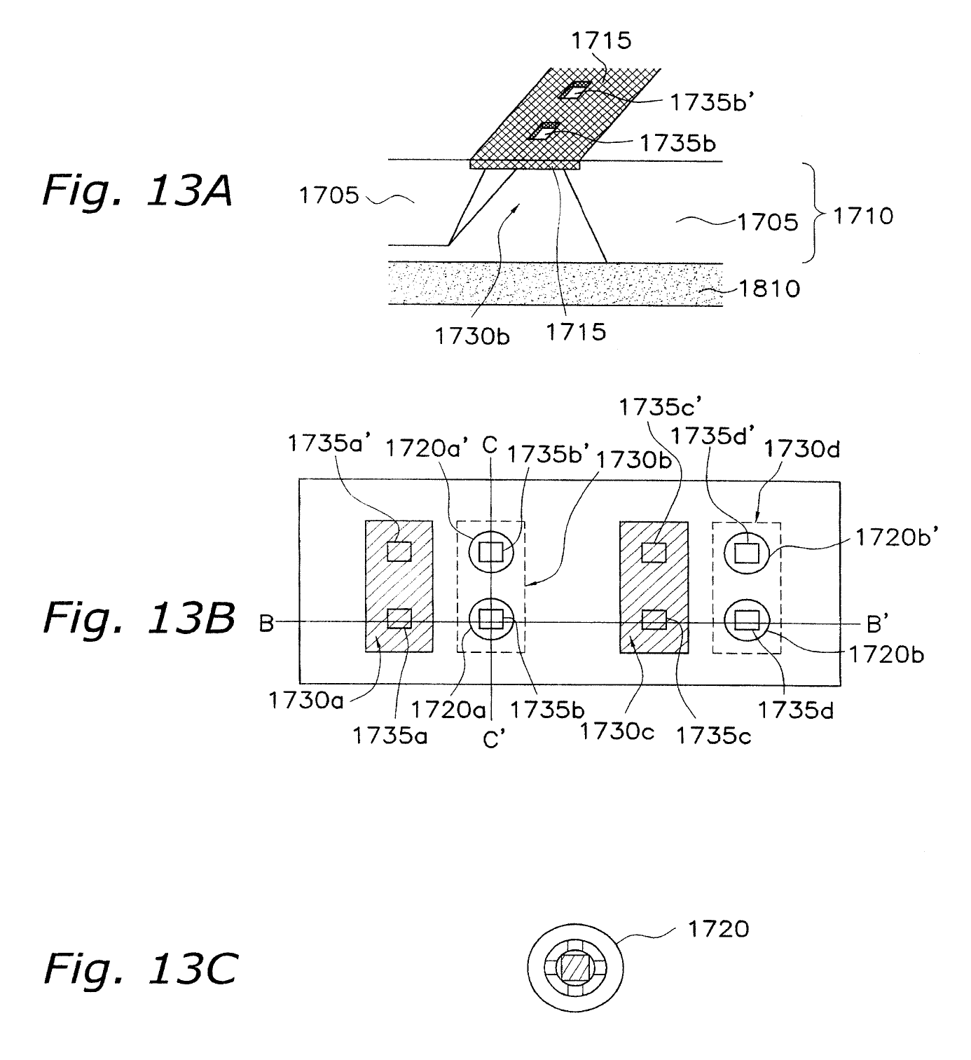

FIG. 12 is an example of the basic structure of the first embodiment applied to a micropump, FIG. 13A is an enlarged view of a recessed portion 1730b, FIG. 13B is a plan view of the micropump shown in FIG. 12 taken along line A-A′, and FIG. 13C is an enlarged view of a valve.

The micropump includes a resin plate 1610 in which a diaphragm 1620 is formed, a semiconductor substrate 1710, and a resin plate 1810 that is attached to the lower surface of the semiconductor surface (the surface opposite the surface on which the resin plate 1610 is formed).

The semiconductor substrate 1710 includes a semiconductor substrate main unit 1705 and thin portions 1715. In addition, recessed portions 1730a-1730d (recessed portions 1730) are formed by the thin portions 1715 and the semiconductor substrate main unit 1705. The recessed portions 1730a, 1730c guide fluid from the upper surface of the semiconductor substrate to the lower surface thereof, and the recessed portions 1730b, 1730d guide fluid from the lower surface of the semiconductor substrate to the upper surface thereof. In addition, through holes 1735a, 1735a′, 1735b, 1735b′, 1735c, 1735c′, 1735d, and 1735d′ (through holes 1735) are provided in the thin portion 1715. The through holes 1735a, 1735a′ are formed to correspond to the recessed portion 1730a, the through holes 1735b, 1735b′ are formed to correspond to the recessed portion 1730b, the through holes 1735c 1735c′ are formed to correspond to the recessed portion 1730c, and the through holes 1735d, 1735d′ are formed to correspond to the recessed portion 1730d. The resin plate 1610 is formed on a thermal oxide film 1772 and an oxide film 1774 disposed on the semiconductor substrate 1710. The diaphragm 1620 is formed in the resin plate 1610. The diaphragm 1620 is formed such that it has pressure chambers 1660a, 1660b (pressure chambers 1660) that respectively separate fluid from the through holes 1735b, 1735b′. A piezoactuator 1630 is arranged on top of the diaphragm 1620 of the resin plate 1610, and serves to oscillate the diaphragm 1620. The valves 1720a, 1720a′, 1720b, 1720b′ (valves 1720) are formed on the portions of the semiconductor substrate 1710 having through holes 1735 therein, and the through holes 1735 serve as fluid paths. The valves 1720 are formed from disk-shaped valves made of polysilicon that are shaped so that they close the fluid pathways, and four arms that are fixed to the substrate on one side thereof and support the valves (refer to FIG. 13C). When the formation of the through holes, valves, and pressure chambers for each of the recessed portions 1730 is completed, they are configured as follows. Two through holes (1735a, 1735a′) are provided for the recessed portion 1730a, and two through holes (1735c, 1735c′) are provided for the recessed portion 1730c. On the other hand, two through holes (1735b, 1735b′), two valves (1720a, 1720a′), and two pressure chambers (pressure chambers 1660a, 1660b) are provided for the recessed portion 1730b. Two through holes (1735d, 1735d′) and two valves (1720b, 1720b′) are provided for the recessed portion 1730d. In the present embodiment, two through holes, two valves, and the like are provided for one recessed portion, but two or more of these items may also be provided.

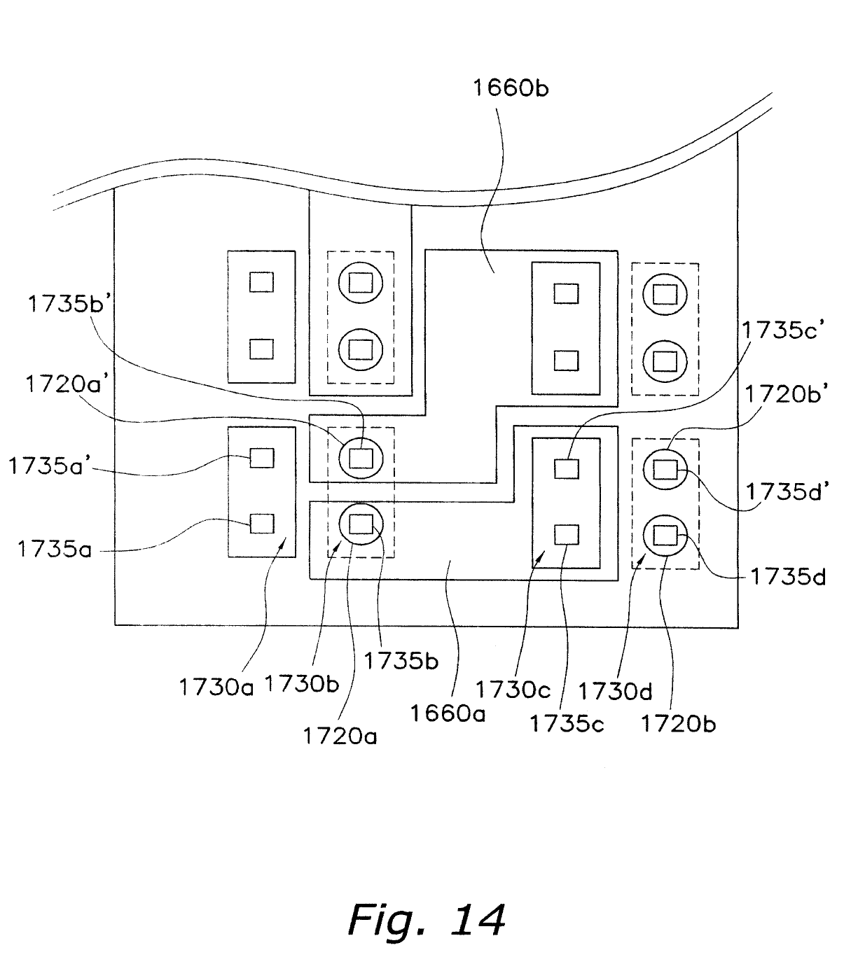

A micropump like that described above can have valves formed at a high density on a plurality of through holes because a plurality of through holes 1735 can be formed in the thin portion 1715. In addition, the semiconductor device is mechanically and structurally strengthened by the thin portion 1715, flexion of the semiconductor device will be reduced, and thus the resin plates and valves can be made so that they are difficult to delaminate from the semiconductor device. Furthermore, micropumps having a variety of shapes can be obtained by forming the pressure chambers 1660 in which the valves 1720 are provided into various shapes, for example the L-shapes or step shapes shown in FIG. 14.

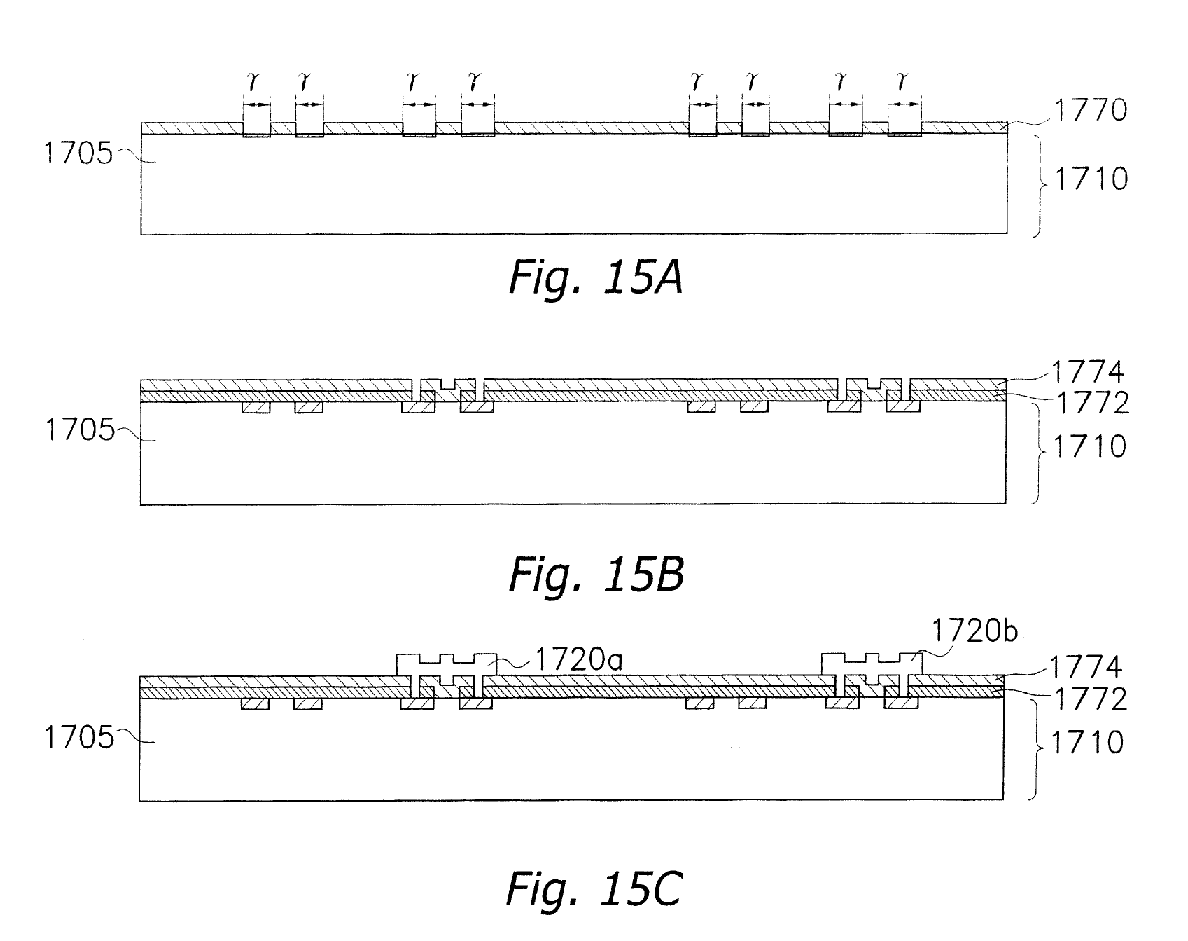

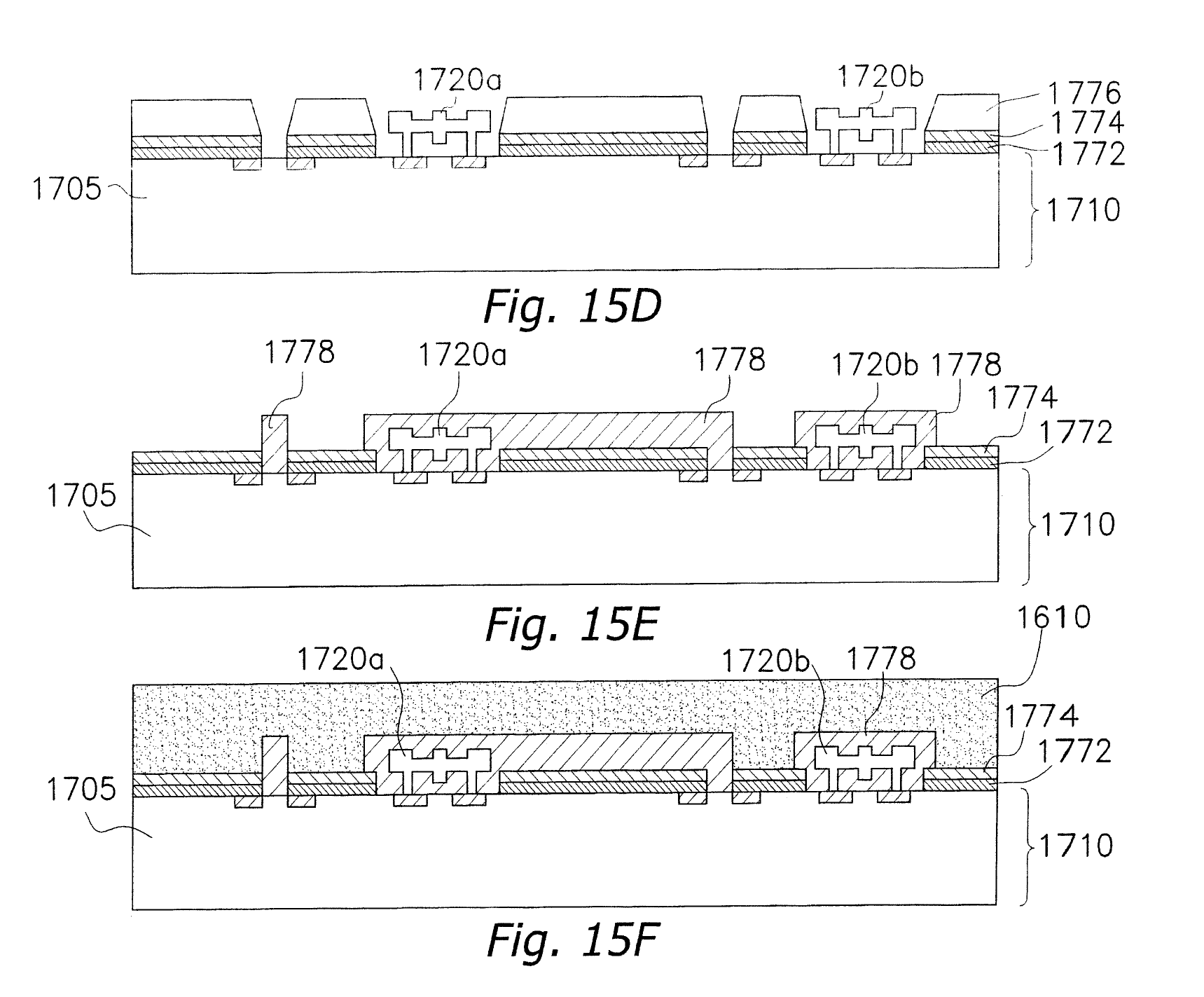

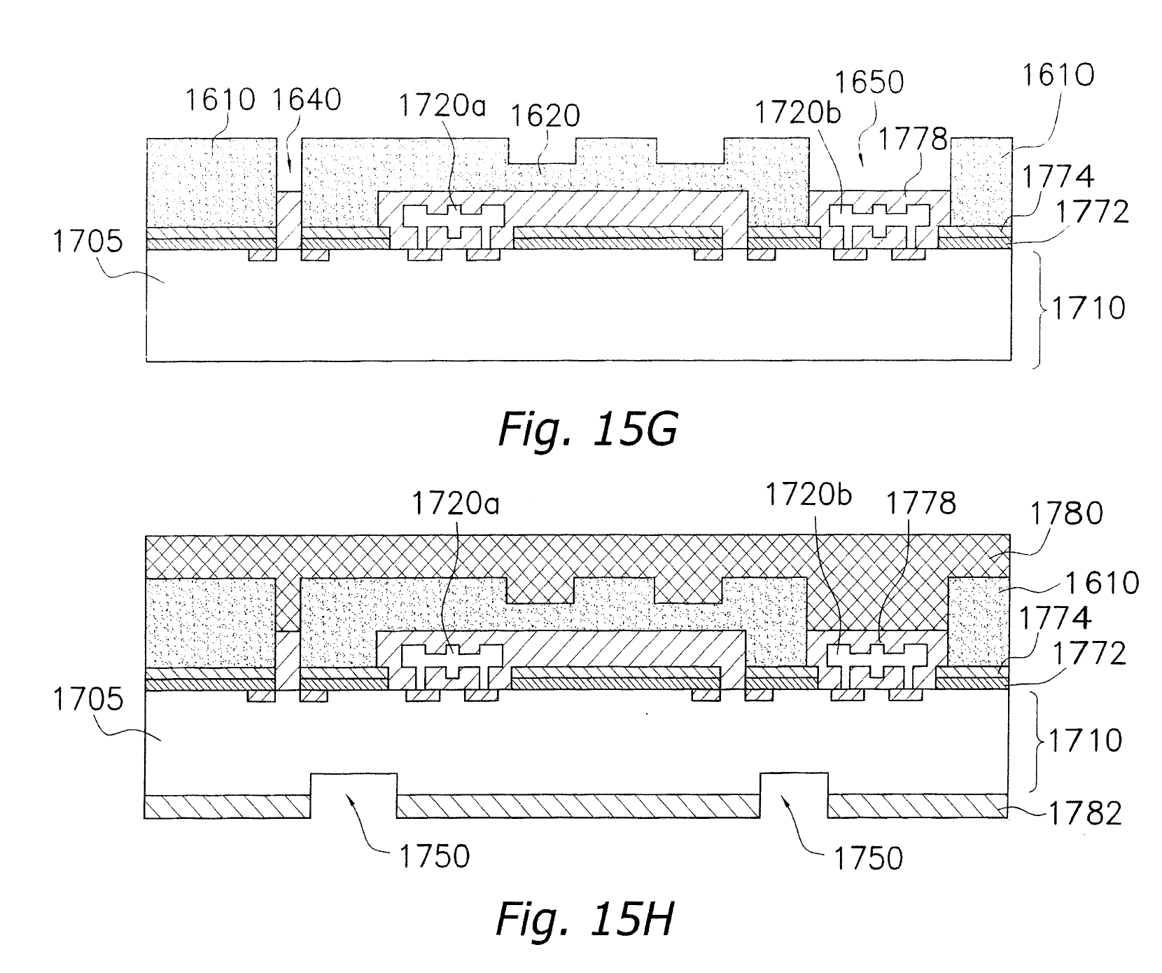

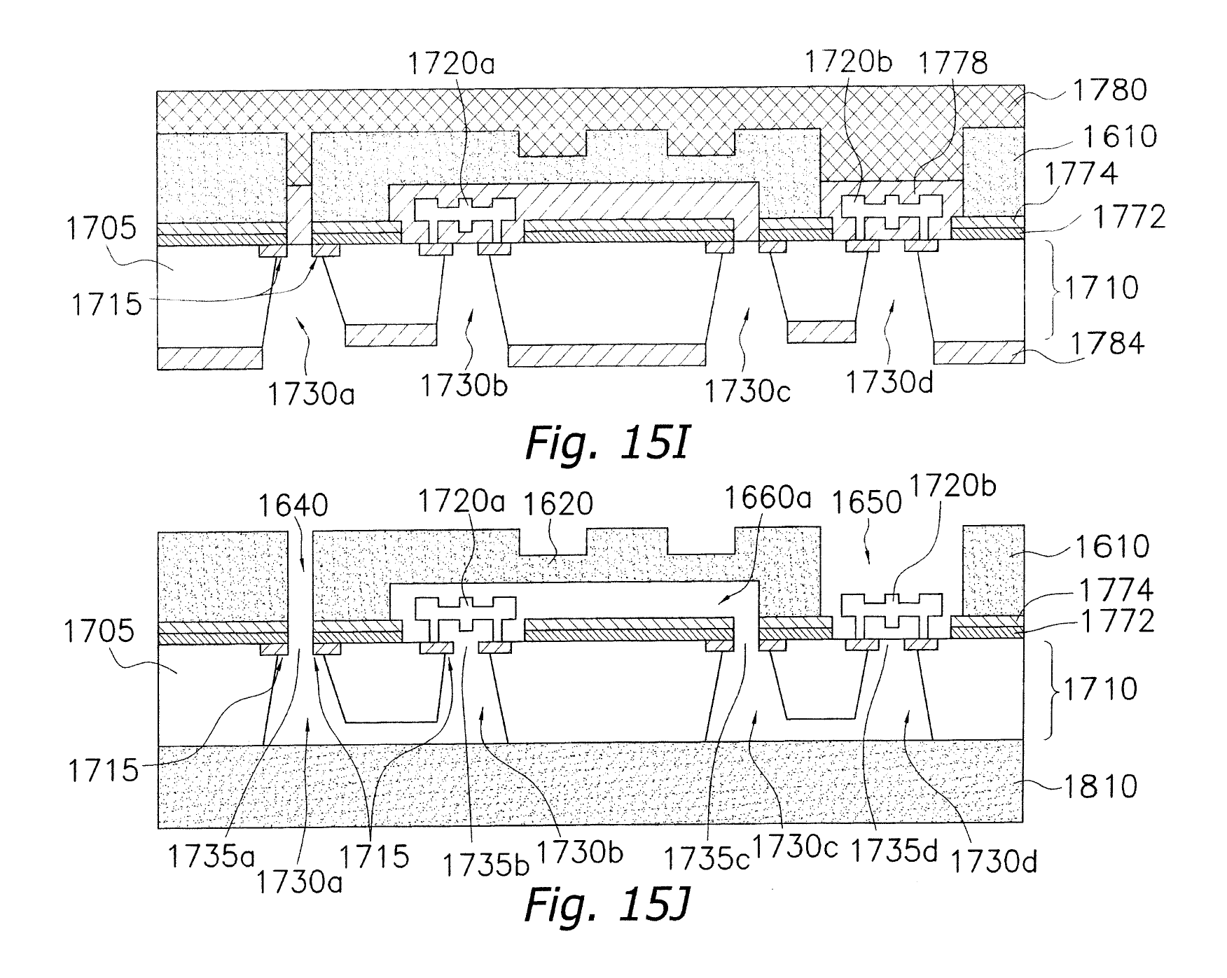

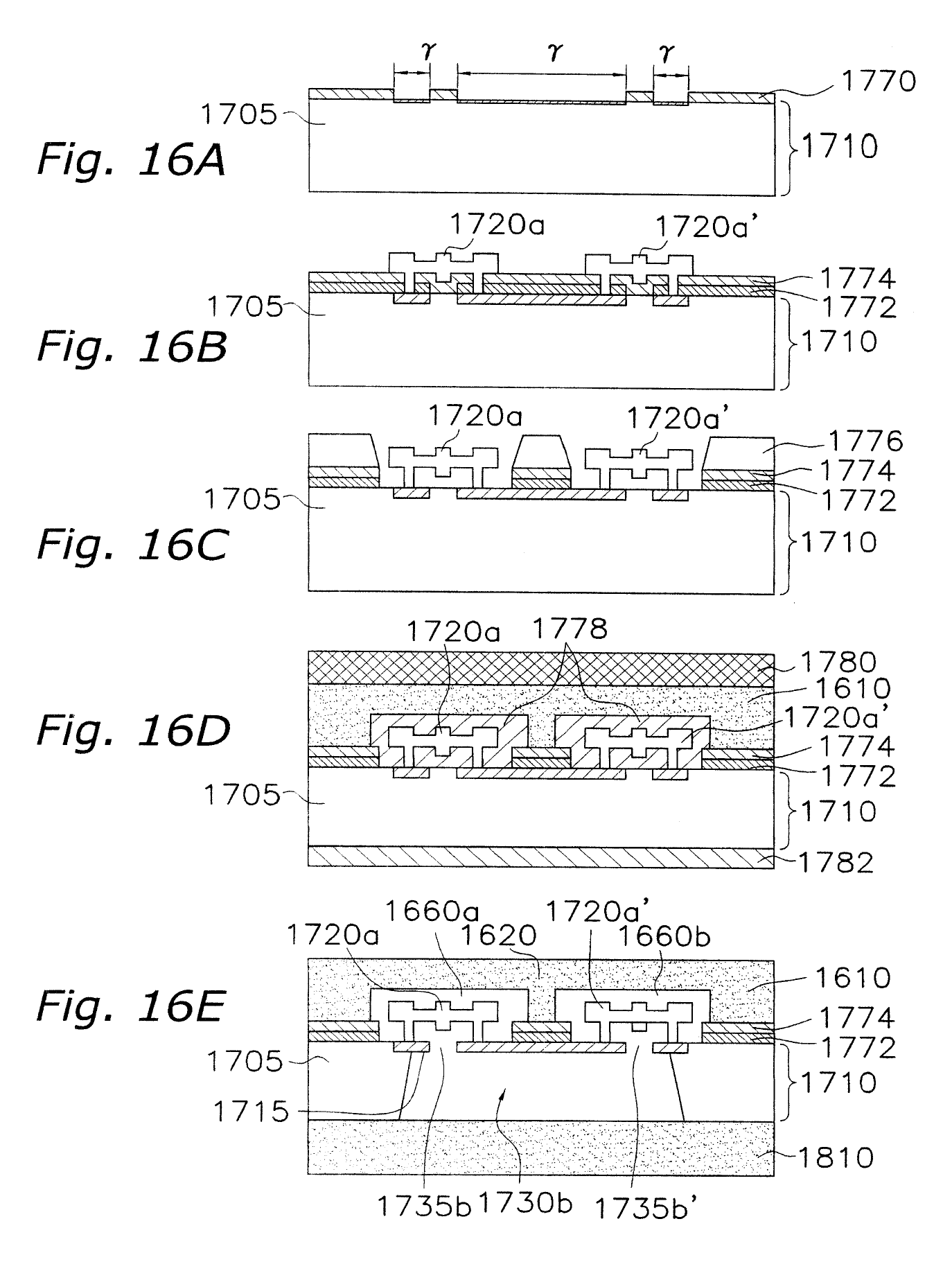

FIGS. 15A-J show steps in the production of the essential elements of the micropump described above, and are cross-sectional views taken along line B-B′ of FIG. 13B. FIG. 15J shows the structure of the essential elements of the micropump described above, and is a cross-sectional view taken along line B-B′ of FIG. 13B. FIGS. 16A-E show steps in the production of the essential elements of the micropump described above, and are cross-sectional views taken along line C-C′ of FIG. 13B. FIG. 15E shows the structure of the essential elements of the micropump described above, and is a cross-sectional view taken along line C-C′ of FIG. 13B.

The structure of the essential elements of the micropump shown in FIG. 15J is identical to that shown in FIG. 12, and the essential elements of the micropump shown in FIG. 16E is as described below.

The micropump includes a semiconductor substrate 1710, and two resin plates 1610, 1810 that are attached to both surfaces of the semiconductor substrate 1710. A semiconductor substrate main unit 1705 and a thin portion 1715 are formed in the semiconductor substrate 1710. In addition, a recessed portion 1730b is formed by the thin portion 1715 and the semiconductor substrate main unit 1705. In the recessed portion 1730b, the through holes 1735b, 1735b′ are formed in the thin portion 1715, and the valves 1720a, 1720a′ are respectively formed on the through holes 1735b, 1735b′.

The resin plate 1610 is formed on a thermal oxide film 1772 and an oxide film 1774 disposed on the semiconductor substrate 1710. The diaphragm 1620 is formed in the resin plate 1610. The diaphragm 1620 has pressure chambers 1660a and 1660b formed between the diaphragm 1620 and the upper surface of the semiconductor substrate 1710. A piezoactuator (not shown in FIG. 16) that serves to oscillate the diaphragm 1620 is attached on top of the diaphragm 1620, and changes the pressure inside the pressure chambers 1660a, 1660b.

Steps in the production of the essential elements of the micropump will be described below with reference to FIGS. 15A-J and FIGS. 16A-E.

First, in the aforementioned method, a mask 1770 having openings # therein in which a dopant is infused is formed on an upper surface of a semiconductor substrate 1710 that is, for example, <100> silicon. The mask 1770 is, for example, composed of a resist, an oxide film, or the like. Then, a dopant such as boron or the like is infused in the upper surface of the semiconductor substrate 1710 through the openings # in the mask 1770 (refer to FIG. 15A, FIG. 16A). The portions # in which the dopant is infused correspond to the recessed portions 1730a-1730d (recessed portions 1730).

The mask 1770 is then removed, an thermal oxide film 1772 is formed, and an oxide film 1774 is deposited on the thermal oxide film 1772. The thermal oxide film 1772 and the oxide film 1774 each have openings therein in order for the valves 1720 to be formed (refer to FIG. 15B). In addition, the thermal oxide film 1772 and the oxide film 1774 can also be used to form semiconductor elements on portions other than the valves 1720, as well as to protect semiconductor elements.

The valves 1720 are then formed on the thermal oxide film 1772 and the oxide film 1774 (refer to FIG. 15C, FIG. 16B). The valves 1720 are, for example, formed from poly-Si by means of CVD and plasma etching with a mask produced from a photoresist.

Portions that guide fluid from the upper surface of the semiconductor substrate to the lower surface thereof and portions that guide fluid from the lower surface of the semiconductor substrate to the upper surface thereof, in other words, a resist 1776 having openings in portions thereof that correspond to the recessed portions 1730, is formed on the thermal oxide film 1772 and the oxide film 1774. The thermal oxide film 1772 and the oxide film 1774 that are in the openings in the resist 1776 are removed therefrom by means of HF (refer to FIG. 15D, FIG. 16C).

In order to form fluid paths in the resin plate 1610, a resist 1778 is applied to portions thereof that correspond to an inlet 1640, pressure chambers 1660, and an outlet 1650. An organic film that will become the resin plate 1610 is applied to the resist 1778 by, for example, spin coating. The organic film that corresponds to the inlet 1640, the diaphragm 1620, and the outlet 1650 is removed by, for example, O₂ plasma dry etching, thereby forming the resin plate 1610. A protective layer 1780 is formed on the resist 1778 and the resin plate 1610 that form the recessed portions 1730 and the fluid paths 1750 in the semiconductor substrate 1710. The protective layer 1780 serves to protect the resist 1778 and the resin plate 1610 from the effects of the etching that will be performed on the lower surface of the semiconductor substrate. First, a resist 1782 having openings that correspond to the fluid paths 1750 is formed on the lower surface of the semiconductor substrate, and the fluid paths 1750 are formed by etching from the lower surface of the semiconductor substrate 1710 (refer to FIGS. 15E-H, FIG. 16D).

The resist 1782 is then removed, a resist 1784 having openings that correspond to the recessed portions 1730 is formed on the lower surface of the semiconductor 1710, and the recessed portions 1730 are formed by etching from the lower surface of the semiconductor substrate. Next, the protective layer 1780 is removed, and whole image light exposure is performed from the upper surface of the semiconductor substrate by means of, for example, UV light (FIG. 15I).

After the whole image light exposure, the resist 1778 is removed by means of a developing fluid, and the resin plate 1810 is attached to the lower surface of the semiconductor substrate 1710 to obtain the micropump (refer to FIG. 15J, FIG. 16E).

The positions in which the through holes are formed in this micropump can be controlled by means of the positions in which the dopant is infused, and thus the positions of the through holes can be accurately controlled. Thus, various types of elements and functional components such as valves, pressure chambers, fluid paths, inlets, and outlets can be formed in the surface of the semiconductor substrate with good precision and at a high density. The thin portion can also be formed by means of a selective oxide film as noted above. Here, examples of a semiconductor device having microwiring and a micropump were provided. However, the present invention can be applied to a variety of micromachines such as other microvalves, flow sensors, and optical wiring.

2. Second Embodiment

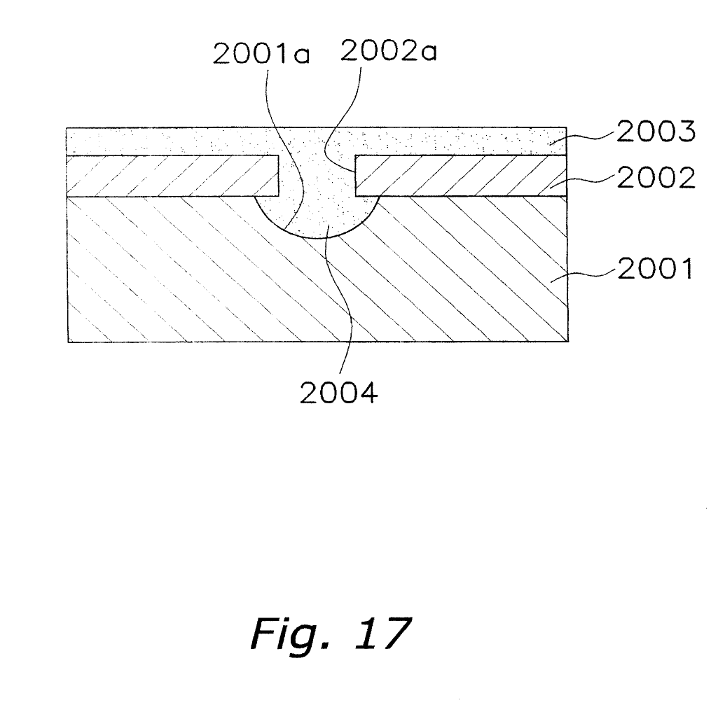

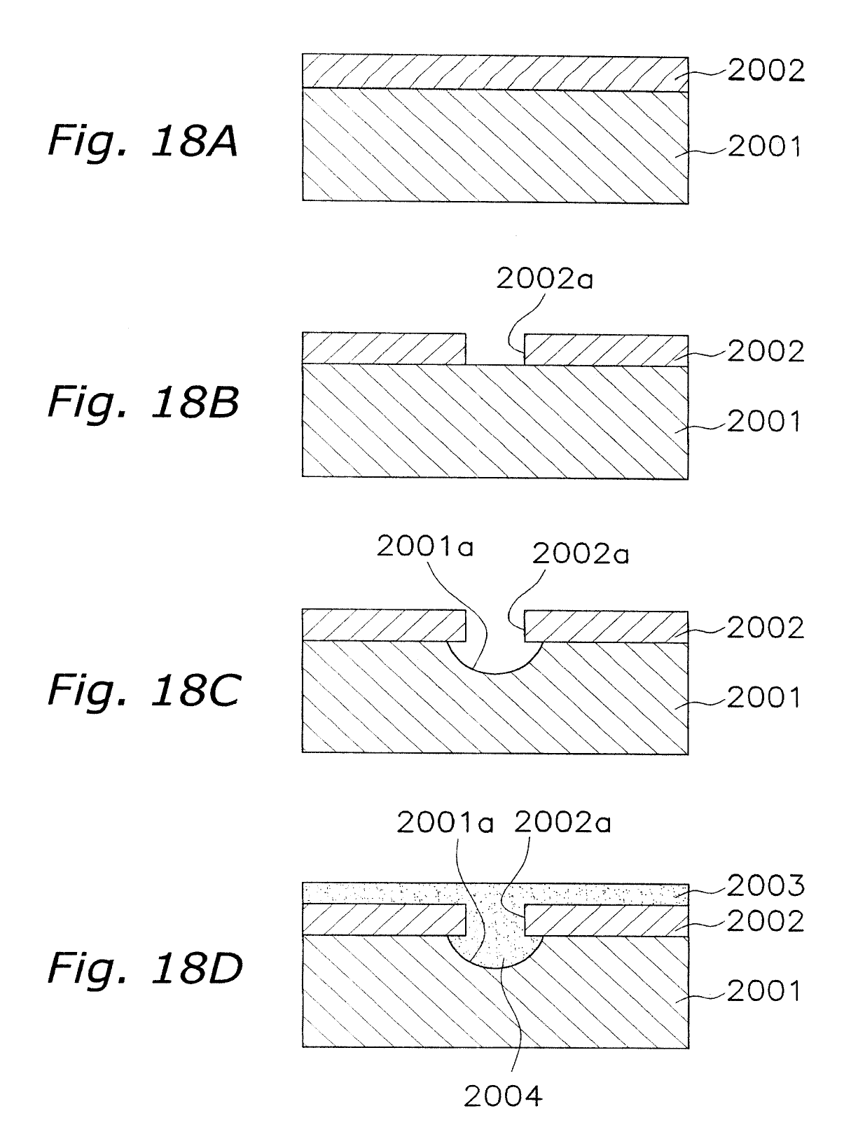

FIG. 17 shows the basic structure of a semiconductor device for micromachines according to a second embodiment of the present invention.

This semiconductor device includes a semiconductor substrate 2001 that is formed with an oxide film, a nitride film, and the like, an inorganic film 2002, and an organic resin (hereinafter, “organic film”) 2003. Depending on the type of device, various functional components may be formed on the semiconductor substrate 2001. The inorganic film 2002 is formed on the upper surface of the semiconductor substrate 2001, and a predetermined patterning is performed. In addition, through holes 2002a are formed at a plurality of positions in the inorganic film 2002, and pass from the upper surface thereof to the lower surface thereof. Here, the inorganic film 2002 may be a metallic film. The organic film 2003 is formed on the upper surface of the inorganic film 2002, and has functional components formed in the interior thereof in accordance with the purpose of the device.

In the upper surface of the semiconductor substrate 2001, approximately semi-circular recessed portions 2001a are formed in the positions that correspond to the through holes 2002a in the inorganic film 2002. The outer diameters of the recessed portions 2001a are formed to be larger than the inner diameters of the through holes in the inorganic film 2002. At the same time that the organic film 2003 is formed on the upper surface of the inorganic film 2002, a portion of the organic film 2003 will be filled into the recessed portions 2001a and the through holes 2002a. In this way, the organic film 2003 filled into the recessed portions 2001a will become attachment organic films 2004.

Portions of the semiconductor device formed in this manner (other than the attachment organic films 2004) will have two inorganic materials that directly adhere to each other between the semiconductor substrate 2001 and the inorganic film 2002, and thus there will be an excellent adhesiveness between the two films. In addition, although the adhesiveness between the inorganic film 2002 and the organic film 2003 is inferior, the attachment organic films 2004 in this embodiment will help to prevent the organic film 2003 from delaminating from the inorganic film 2002. In other words, because the outer diameters of the attachment organic films 2004 are formed to be larger than the inner diameters of the through holes 2002a, even if a force is temporarily applied in a direction that would delaminate the organic film 2003 from the inorganic film 2002, the attachment organic films 2004 unitarily formed with the organic film 2003 will catch the lower lips of the through holes 2002a and prevent the organic film 2002 from delaminating from the inorganic film 2002.

Here, the organic film 2003 is mechanically prevented from delaminating from the inorganic film 2002 by means of the attachment organic films 2004. Thus, the organic film 2003 can be prevented from delaminating from the inorganic film 2002 even if the adhesive surface area between the organic film 2003 and the inorganic film 2002 is comparatively small. In addition, the material selected for use as the organic film 2003 is not limited to one which adheres well to the inorganic film 2002, and thus the degree of freedom one has in the selection of the material for the organic film will be increased. Furthermore, the production process will be simplified because it will not be necessary to form a buffer layer in between the inorganic film 2002 and the organic film 2003.

Next, a method of producing the second embodiment will be described below with reference to FIG. 18.

First, as shown in FIG. 18A, the inorganic film 2002 is formed on the upper surface of the semiconductor substrate 2001 formed from an oxide film, a nitride film, or the like. The inorganic film 2002 may, for example, be a metallic film. Next, as shown in FIG. 18B, the through holes 2002a that pass through the inorganic film 2002 are formed in predetermined locations of the inorganic film 2002. As shown in FIG. 18C, the through holes 2002a in the inorganic film 2002 are used to isotropically etch portions of the semiconductor substrate 2001. This forms approximate semi-circular recessed portions 2001a having outer diameters that are larger than the inner diameters of the through holes 2002a in the lower portions of the through holes 2002a. Next, as shown in FIG. 18D, the organic film 2003 is formed on the upper surface of the inorganic film 2002, and at the same time the organic film 2003 is filled into the through holes 2002a and the recessed portions 2001a. This forms the attachment organic films 2004 in the recessed portions 2001a.

Here, the production process is simplified because the attachment organic films 2004 can be formed at the same time as the organic film 2003 is formed.

3. Third Embodiment

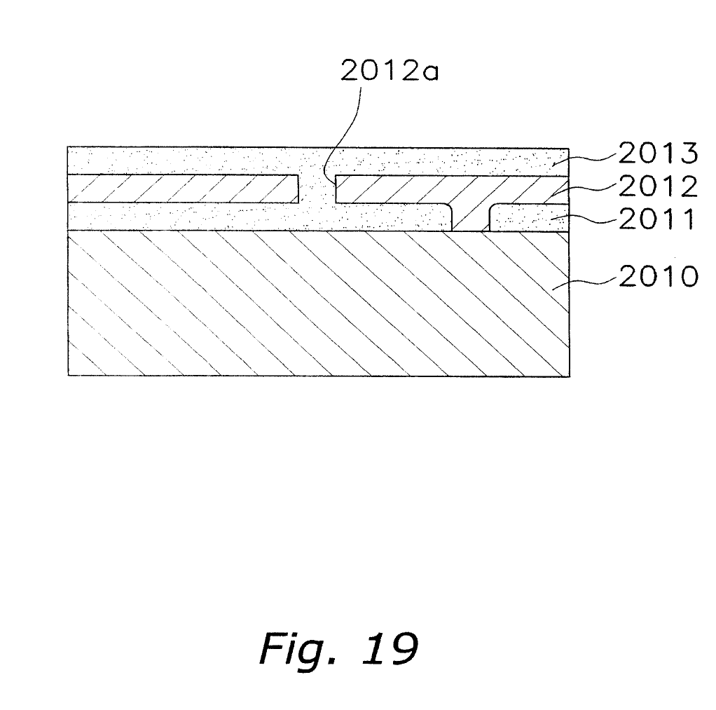

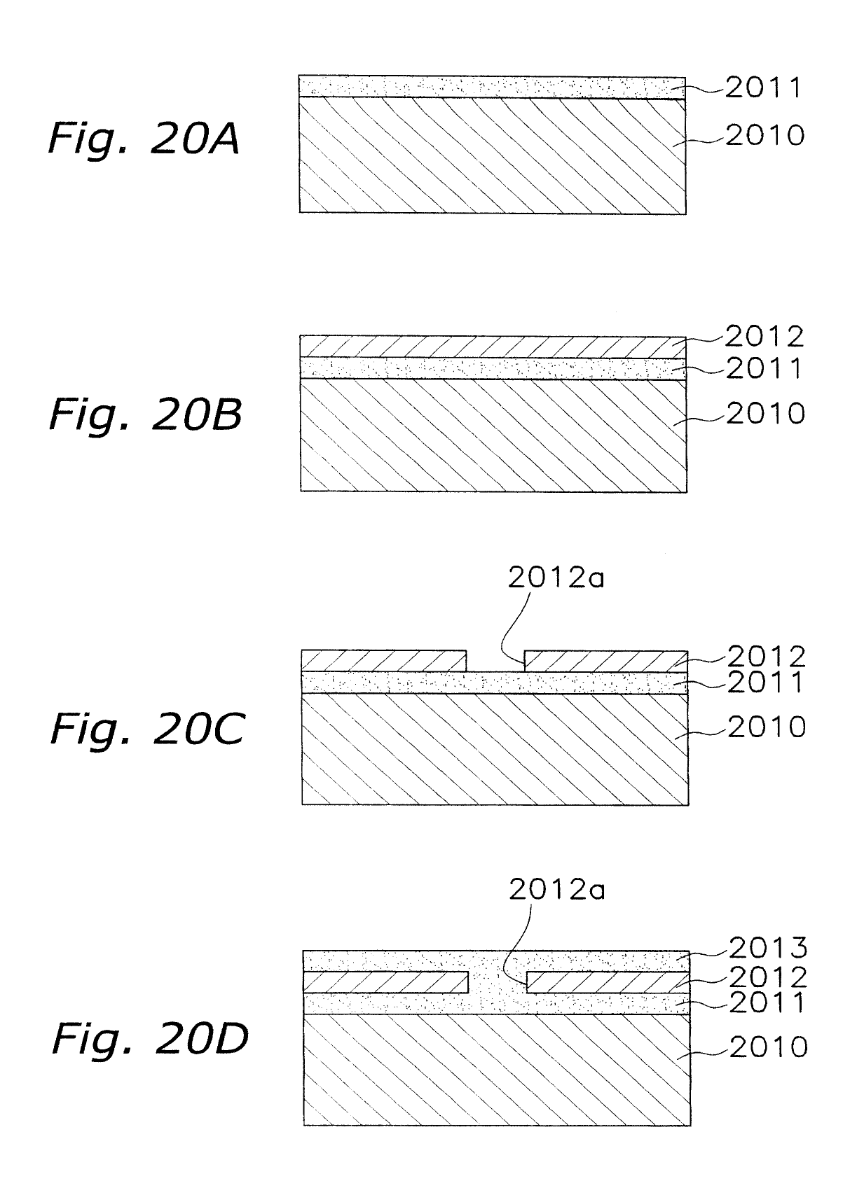

FIG. 19 shows the basic structure of a semiconductor device for micromachines according to a third embodiment of the present invention.

This semiconductor device includes a semiconductor substrate 2010 formed from an oxide film, a nitride film, or the like, a first organic film 2011 that is formed on the upper surface of the semiconductor substrate 2010, an inorganic film 2012, and a second organic film 2013.

The first organic film 2011 is formed on the upper surface of the semiconductor substrate 2010, and, for example, has functional components formed in the interior thereof in accordance with the type of device. Portion of the first organic film 2011 functions as attachment organic films (described below). The inorganic film 2012 is formed on the upper surface of the first organic film 2011, and a predetermined patterning is performed. In addition, through holes 2012a are formed at a plurality of positions in the inorganic film 2012, and pass from the upper surface thereof to the lower surface thereof. Note that through holes may be provided in the first organic film 2011 that pass from the upper surface thereof to the lower surface thereof. In this situation, the inorganic film 2012 is directly adhered to the semiconductor substrate 2010 at a variety of positions via the through holes. The inorganic film 2012 may be a metallic film. The second organic film 2013 sandwiches the inorganic film 2012 between it and the first organic film 2011, is formed on the upper surface of the inorganic film 2012, and is unitarily linked with the first organic film 2011 via the through holes 2012a in the inorganic film 2012.

In a semiconductor device formed as described above, the second organic film 2013 and the first organic film 2011 are formed such that they sandwich the inorganic film 2012, and the first organic film 2011 is formed such that it extends outward further than the inner diameters of the through holes 2012a. Moreover, the second organic film 2013 and the first organic film 2011 are unitarily linked via the through holes 2012a of the inorganic film 2012. Thus, when a force is applied to the second organic film 2013 in a direction that could delaminate it from the inorganic film 2012, the first organic film 2011 will carry out the same function as the attachment organic films in the second embodiment, and prevent the second organic film 2013 from delaminating from the inorganic film 2012.

In this embodiment, the adhesiveness between the semiconductor substrate 2010 and the first organic film 2011 is inferior because the attachment is between an inorganic material and an organic material. However, no particular problems will occur between the first organic film 2011 and the semiconductor substrate 2010 so long as a force that is capable of delaminating the first organic film 2011 from the semiconductor substrate 2010 is not applied thereto. In addition, in situations in which through holes are formed in a portion of the first organic film 2011 and the inorganic film 2012 is directly adhered to the semiconductor substrate 2010, the attachment positions will have excellent adhesiveness because two inorganic materials are bonded to each other, and the first organic film 2011 can be prevented from delaminating from the semiconductor substrate 2010 due to the adhesion between the inorganic film 2012 and the semiconductor substrate 2010.

Here, like above, the second organic film 2013 will be mechanically prevented from delaminating from the inorganic film 2012 by means of the first organic film 2011. Thus, the same effect as noted above will be obtained. In particular, because portions of the first organic film 2011 can function as attachment organic films, it will not be necessary to form special attachment organic films and the production process can therefore be simplified.

Next, a method of producing the third embodiment will be described below with reference to FIG. 20.

First, as shown in FIG. 20A, the first organic film 2011 is formed on the upper surface of the semiconductor substrate 2010 formed from an oxide film, a nitride film, or the like. Next, as shown in FIG. 20B, the inorganic film 2012 is formed on the upper surface of the first organic film 2011, and then as shown in FIG. 20C, the through holes 2012a that pass through the inorganic film 2012 are formed in predetermined locations in the inorganic film 2012. Then, as shown in FIG. 20D, the second organic film 2013 is formed on the upper surface of the inorganic layer 2012, and the second organic film 2013 is thereby unitarily linked with the first organic film 2011 via the through holes 2012a.

4. Other Embodiments

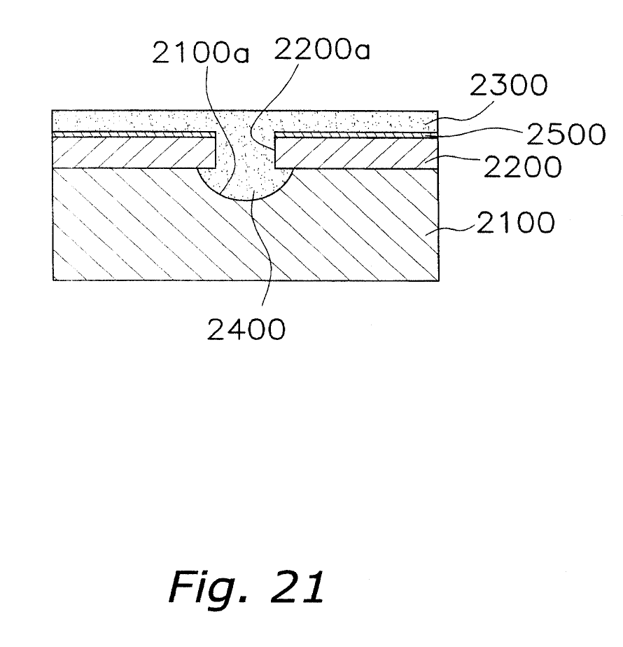

(a) A buffer layer may be provided in between the inorganic film and the organic film in each of the aforementioned embodiments. An example of this is shown in FIG. 21.

In FIG. 21, a buffer layer 2500 is formed between the inorganic film 2200 and the organic film 2300. The other structures are identical to those shown in the second embodiment. In other words, this semiconductor device includes a semiconductor substrate 2100 formed from an oxide film, a nitride film, and the like, an inorganic film 2200, and an organic resin (hereinafter, “organic film”) 2300. Depending on the type of device, various functional components may be formed on the semiconductor substrate 2100. The inorganic film 2200 is formed on the upper surface of the semiconductor substrate 2100, and a predetermined patterning is performed. In addition, through holes 2200a are formed at a plurality of positions in the inorganic film 2200, and pass from the upper surface thereof to the lower surface thereof. Here, the inorganic film 2200 may be a metallic film. The organic film 2300 is formed on the upper surface of the inorganic film 2200, and has functional components formed in the interior thereof in accordance with the purpose of the device.

In the upper surface of the semiconductor substrate 2100, approximately semi-circular recessed portions 2100a are formed in the positions that correspond to the through holes 2200a in the inorganic film 2200. The outer diameters of the recessed portions 2100a are formed to be larger than the inner diameters of the through holes 2200a in the inorganic film 2200. At the same time that the organic film 2300 is formed on the upper surface of the inorganic film 2200, a portion of the organic film 2300 will be filled into the recessed portions 2100a and the through holes 2200a. In this way, the organic film 2300 filled into the recessed portions 2100a will become attachment organic films 2400. This structure will further improve the adhesiveness between the inorganic film 2200 and the organic film 2300.

(b) In the second embodiment of the invention, the attachment organic films 2004 have approximately semi-circular shapes. However, this embodiment is not limited with respect to the shapes of the attachment organic films. The inorganic film may be formed such that it is sandwiched by organic films, and the organic film may be unitarily linked with attachment organic films having shapes that cannot pass through the through holes.

### EXAMPLE 6

Micropump

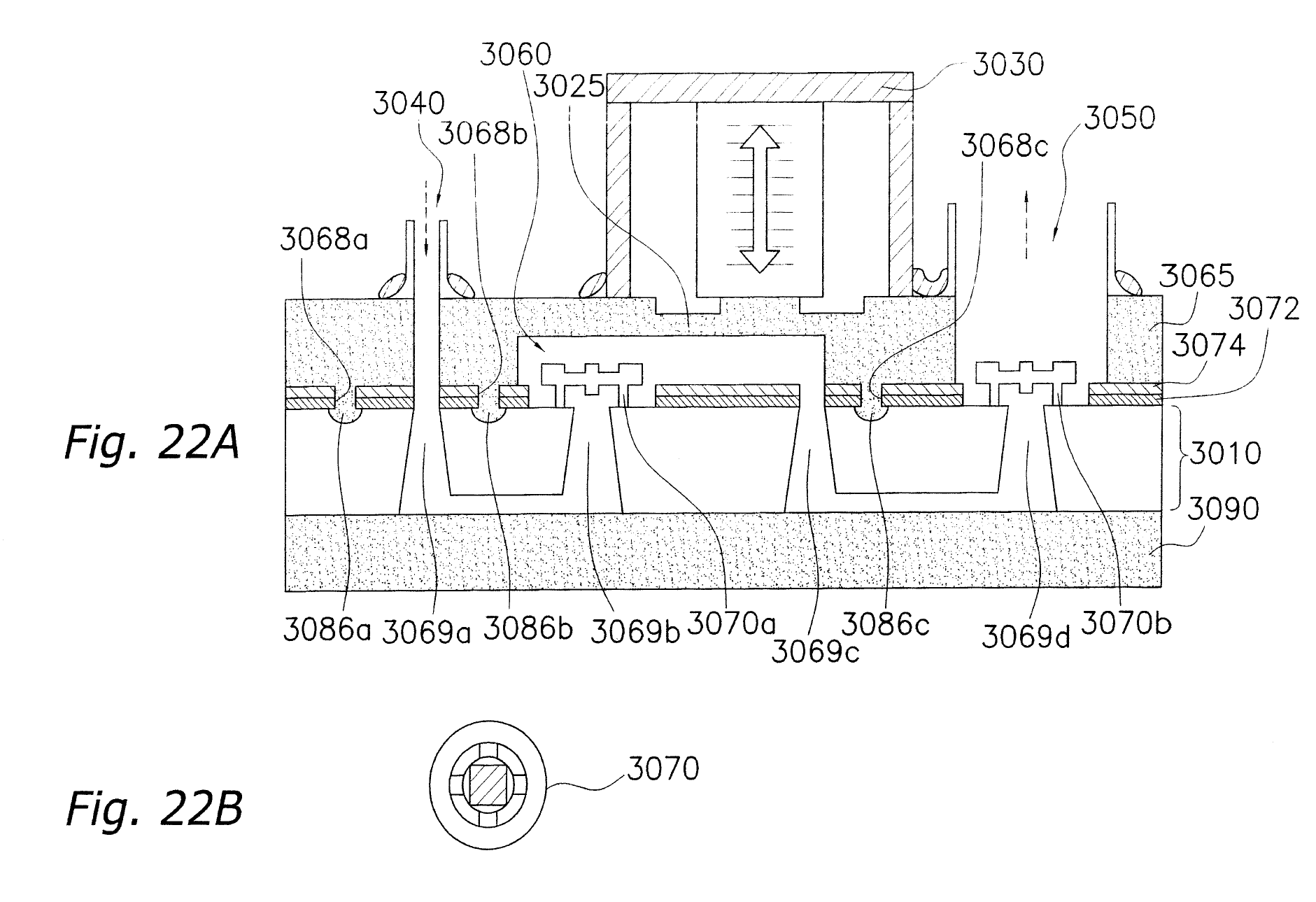

FIG. 22A is an example of the basic structure of the second embodiment applied to a micropump, and FIG. 22B is an enlarged view of a valve. The micropump includes an organic film 3065 in which a diaphragm 3025 is formed, a semiconductor substrate 3010, and an organic film 3090 that is attached to the lower surface of the semiconductor substrate (i.e., the surface of the semiconductor substrate that is opposite the surface on which the organic film 3065 is formed).

Fluid paths 3069a-3069d (fluid paths 3069) are formed in the semiconductor substrate 3010. The fluid paths 3069a, 3069c guide fluid from the upper surface of the semiconductor surface to the lower surface thereof, and the fluid paths 3069b, 3069d guide fluid from the lower surface of the semiconductor surface to the upper surface thereof. In addition, attachment organic films 3086a-3086c (attachment organic films 3086) are formed inside the semiconductor substrate 3010. The attachment organic films 3086 are unitarily linked with the organic film 3065 via through holes 3068a-3068c (through holes 3068) formed through a thermal oxide film 3072 and an oxide film 3047, are approximately semi-circular in shape, and have outer diameters that are larger than the inner diameters of the through holes 3068. The diaphragm 3025 is formed on the thermal oxide film 3072 and the oxide film 3074 that are formed on the semiconductor substrate 3010, and is formed so as to have a pressure chamber 3060 that serves to guide fluid from the fluid path 3069b to the fluid path 3069c. A piezoactuator 3025 is arranged on top of the diaphragm 3065 of the organic film 3025, and serves to oscillate the diaphragm 3030. Valves 3070a, 3070b (valves 3070) are formed on top of the silicon substrate 3010 having the fluid paths 3069 therein. The valves 3070 are formed from disk-shaped valves made of polysilicon that are shaped so that they close the fluid paths, and four arms that are fixed to the substrate on one side thereof and support the valves (refer to FIG. 22B).

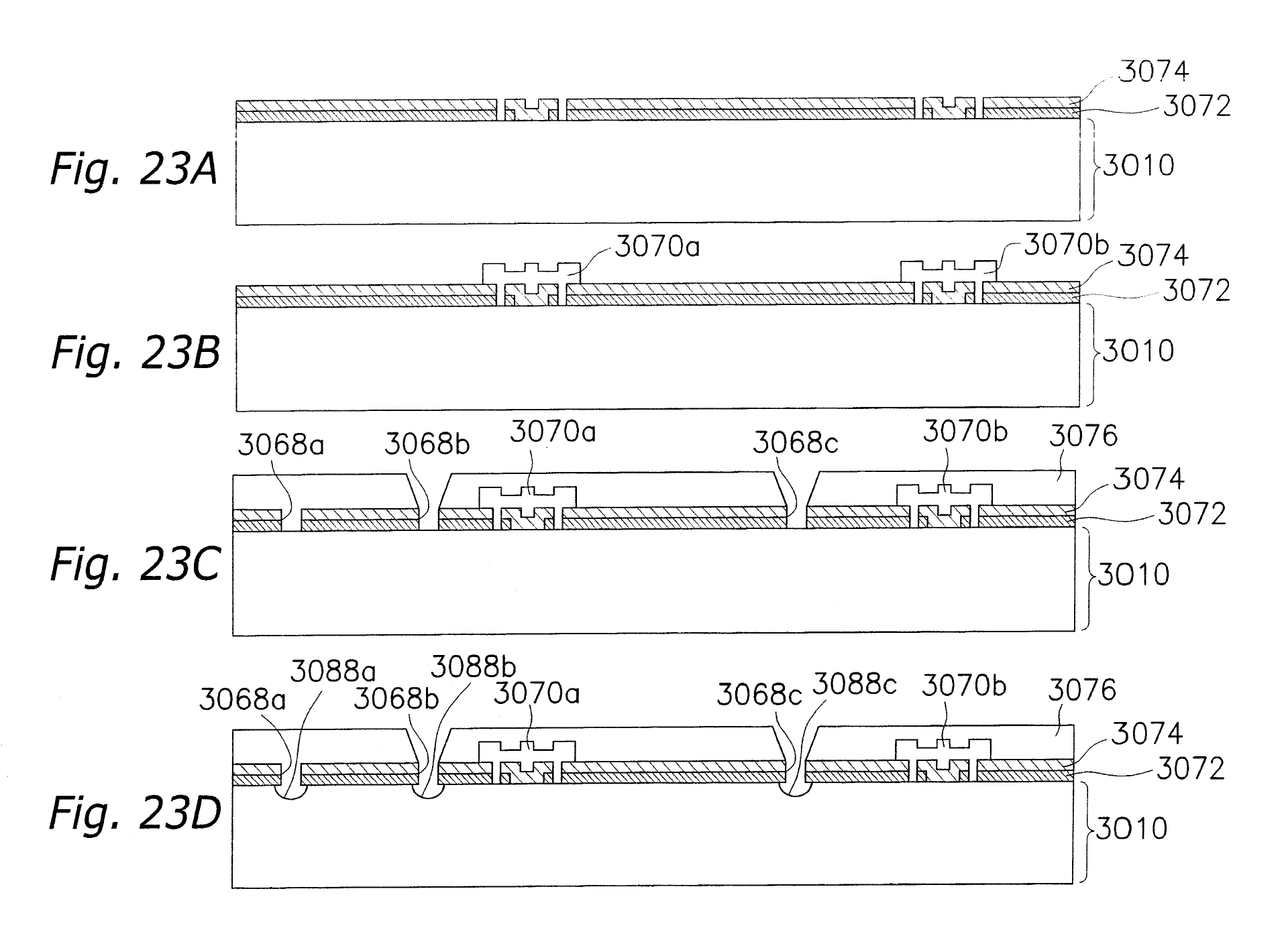

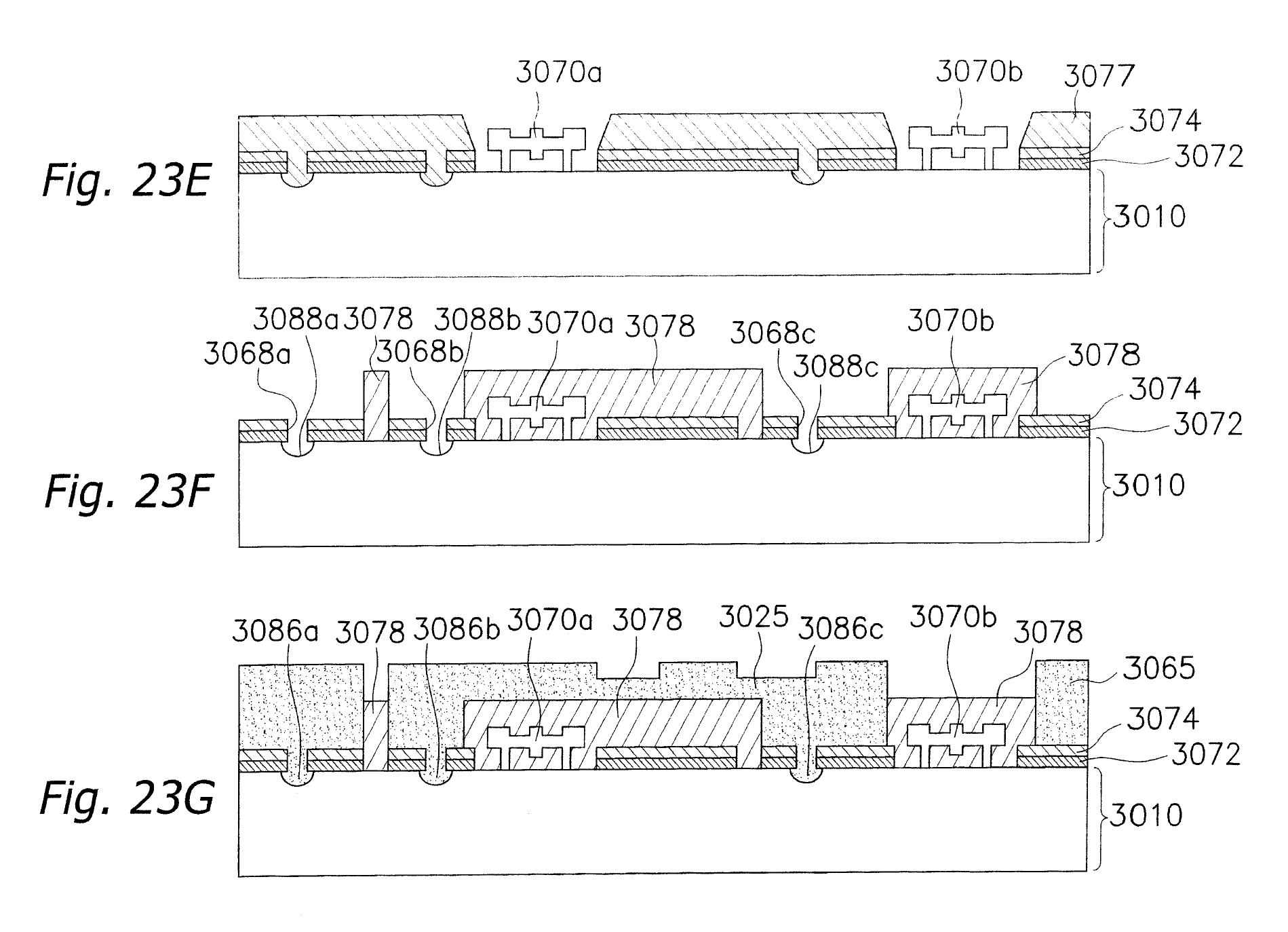

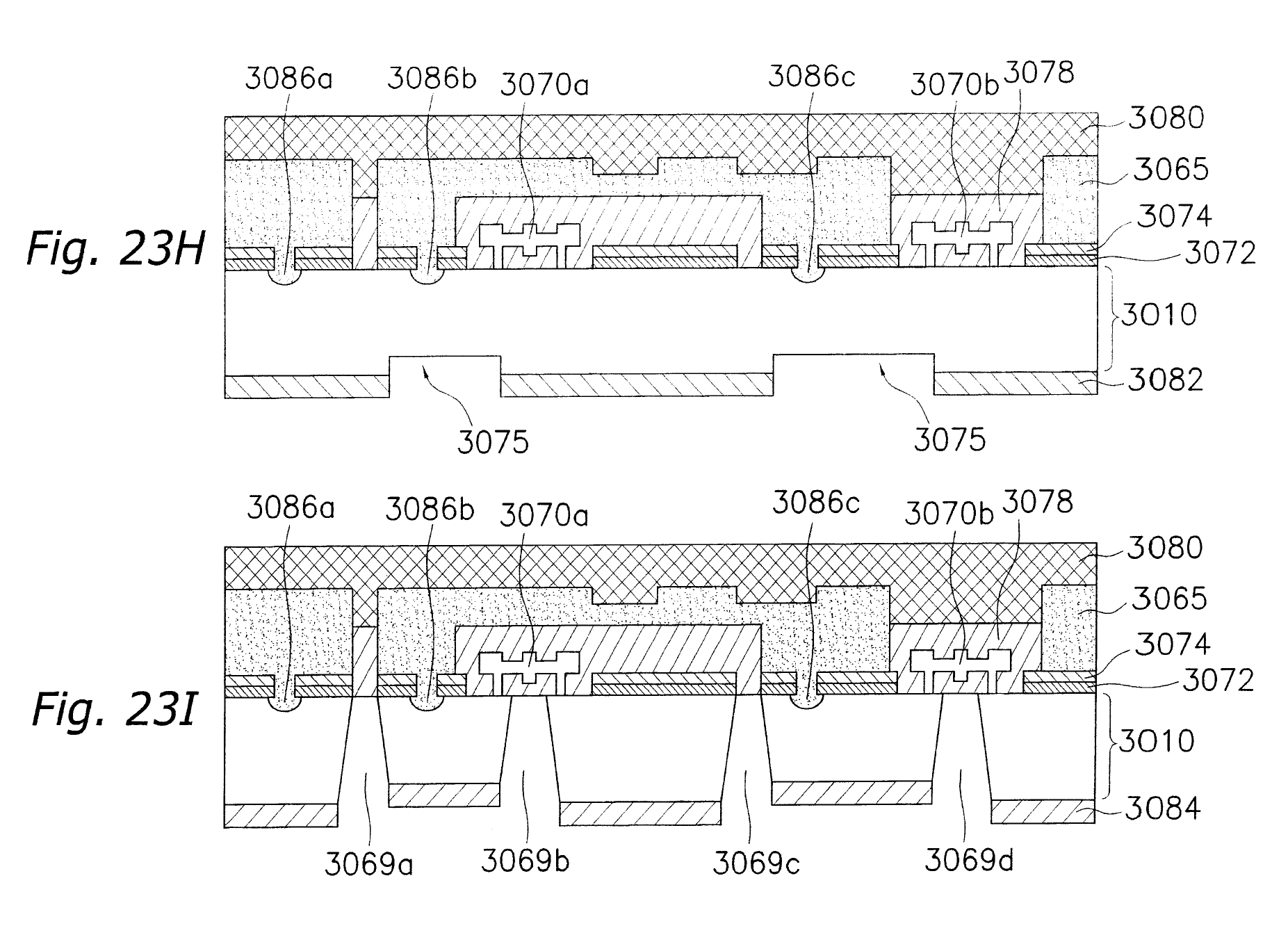

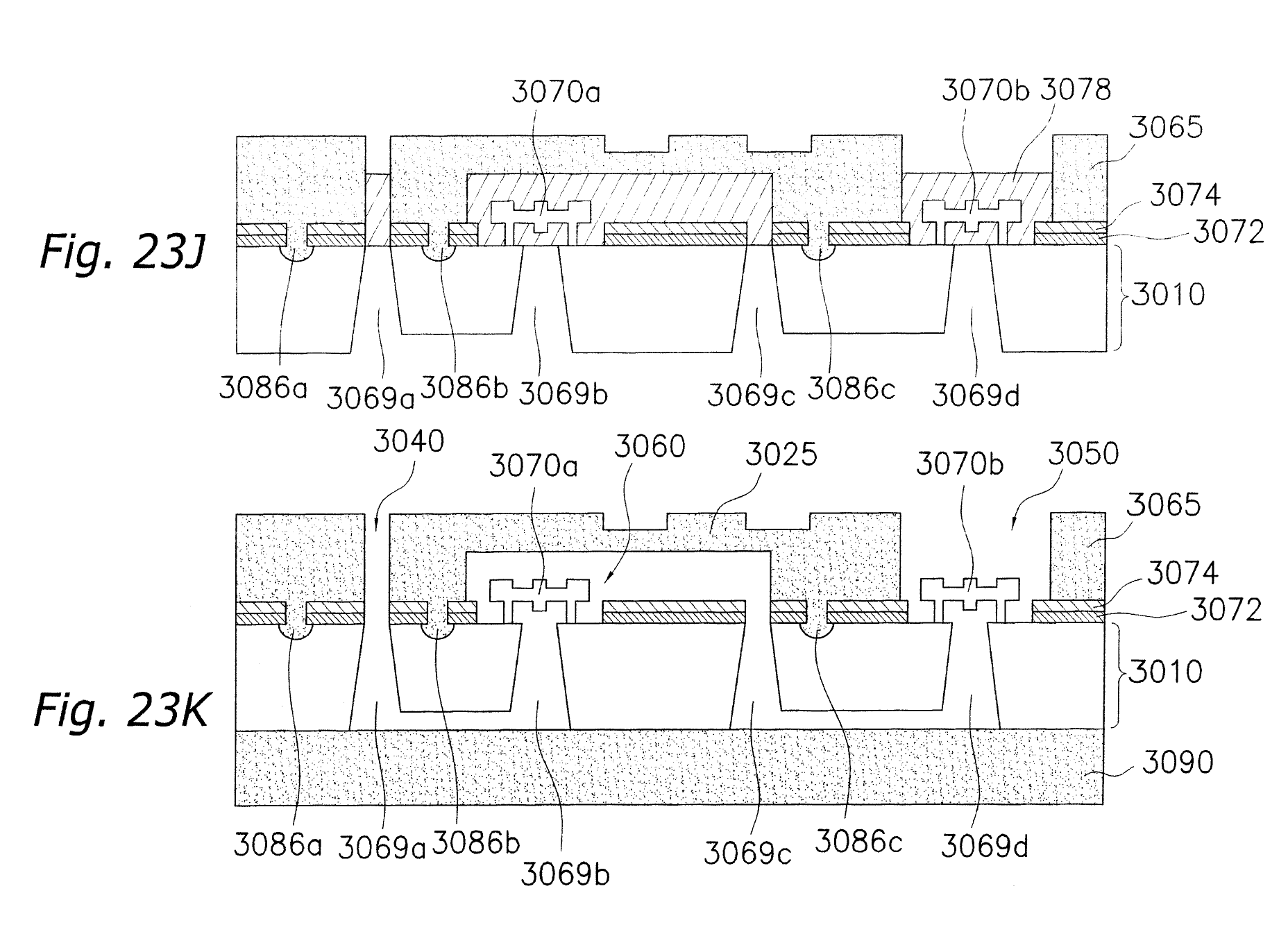

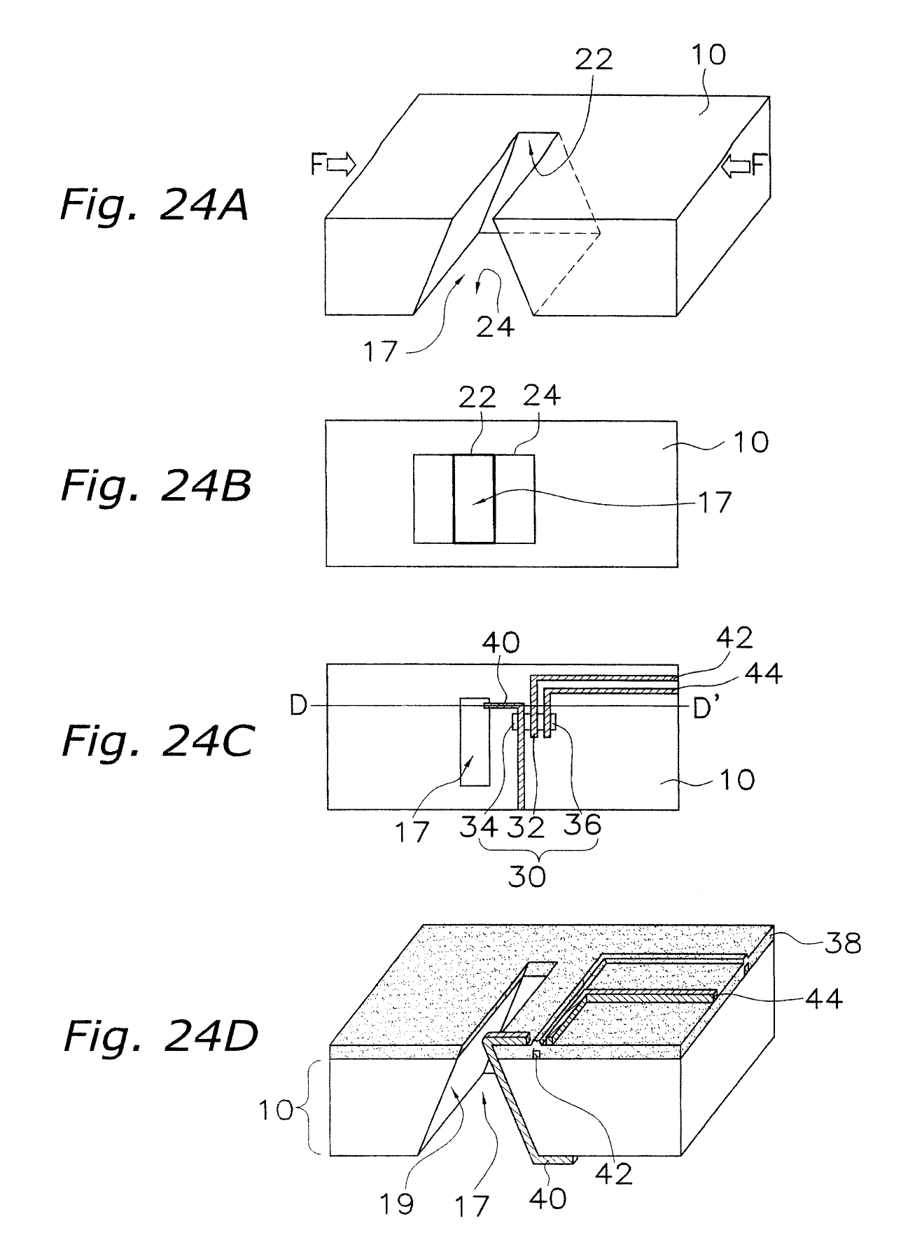

FIGS. 23A-K show steps in the production of the essential elements of the micropump shown in FIG. 22A. Steps in the production of the essential elements of the micropump will be described below with reference to the aforementioned figures.

First, in the method noted above, the thermal oxide film 3072 is formed on the upper surface of the semiconductor substrate 3010 that is, for example, a <100> silicon substrate and oxide film 3072 is formed on the thermal oxide film 3072. The thermal oxide film 3072 and the oxide film 3074 each have openings therein in order for the valves 3070 to be formed (refer to FIG. 23A). In addition, the thermal oxide film 3072 and the oxide film 3074 can also be used to form semiconductor elements on portions other than the valves 3070 as well as to protect semiconductor elements.

The valves 3070 are then formed on the thermal oxide film 3072 and the oxide film 3074 (refer to FIG. 23B). The valves 3070 are, for example, formed from poly-Si by means of CVD and plasma etching with a mask produced from a photoresist.

A resist 3076 having openings therein that correspond to the through holes 3068 inside the thermal oxide film 3072 and the oxide film 3074 is formed on the thermal oxide film 3072 and the oxide film 3074. The thermal oxide film 3072 and the oxide film 3074 that are in the openings of the resist 3076 are then removed by means of HF, thus forming the through holes 3068a-3068c (refer to FIG. 23C).

Then, recessed portions 3088a-3088c that are approximately semi-circular in shape and which have outer diameters that are larger than the inner diameters of the through holes 3068 are formed by isotropically etching the resist 3076 (refer to FIG. 23D). SF₆ is an example of the gas that can be used in the dry etching.

The resist 3076 is removed, a resist 3077 having openings therein for the valves 3070 is formed, and the thermal oxide film 3072 and oxide film 3074 in the openings is removed by means of HF (refer to FIG. 23E).

The resist 3077 is removed, and a resist 3078 is applied to the portions which correspond to an inlet 3040, the pressure chamber 3060, and outlet 3050 in order to form the fluid paths in the organic film 3065 (refer to FIG. 23F).

The organic film 3065 is applied to the resist 3078 by, for example, spin coating. When this occurs, the organic film 3065 will also be infused into the recessed portions 3088a-3088c via the through holes 3068a-3068c, thereby forming the attachment organic films 3086a-3086c. Next, the organic film 3065 that corresponds to the inlet 3040, the diaphragm 3025, and the outlet 3050 is removed by means of, for example, O₂ plasma dry etching, thereby forming the organic film 3065 (refer to FIG. 23G).

A protective layer 3080 is formed on the resist 3078 and the organic film 3065 that form the fluid path 3069 and the fluid path 3075 in the semiconductor substrate 3010. The protective layer 1780 serves to protect the resist 3078 and the organic film 3065 from the effects of the etching that will be performed on the lower surface of the semiconductor substrate. First, a resist 3082 having openings that correspond to the fluid path 3075 is formed on the lower surface of the semiconductor substrate 3010, and the fluid path 3075 is formed by etching from the lower surface of the semiconductor substrate 3010 (refer to FIG. 23H).

The resist 3082 is then removed, a resist 3084 having openings that corresponds to the fluid path 3069 is formed on the lower surface of the semiconductor 3010, and the fluid path 3069 is formed by etching from the lower surface of the semiconductor substrate (refer to FIG. 231).

The protective layer 3080 is removed, and whole image light exposure is performed from the upper surface of the semiconductor substrate by means of, for example, UV light (FIG. 23J).

After the whole image light exposure, the resist 3078 is removed by means of a developing fluid, and the organic film 3090 is attached to the lower surface of the semiconductor substrate 3010 to obtain the micropump (refer to FIG. 23K).

In this micropump, the pressure chamber 3060 is formed inside the organic film 3065. Thus, the pressure of the fluid in the pressure chamber 3060 with respect to the organic film 3065 is applied in a direction that attempts to delaminate the organic film 3065 from the thermal oxide film 3072 and the oxide film 3074. However, in this device the organic film 3065 can be prevented from delaminating from the thermal oxide film 3072 and the oxide film 3074 by means of the attachment between the attachment organic films 3068 and the thermal oxide film 3072 and the oxide film 3074.

This embodiment of the present invention can be applied to a variety of micromachines, such as microvalves, flow sensors, optical wiring, and the like.

This application claims priority to Japanese Patent Application Nos. 2002-297563 and 2002-298255. The entire disclosures of Japanese Patent Application Nos. 2002-297563 and 2002-298255 are hereby incorporated herein by reference.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing description of the embodiments according to the present invention are provided for illustration only, and not for the purpose of limiting the invention as defined by the appended claims and their equivalents.

1. A semiconductor device, comprising:
a semiconductor substrate main unit; and
a thin portion that is thinner than the main unit and formed such that a recessed portion is formed in the semiconductor substrate, the thin portion having at least one through hole formed therein;
wherein the thin portion is formed such that the etching rate thereof is slower than that of the main unit.

2. The semiconductor device set forth in claim 1, wherein the thin portion and the main unit are formed to be unitary with each other.

3. The semiconductor device set forth in claim 1, wherein a dopant is infused in the thin portion.

4. The semiconductor device set forth in claim 1, wherein the thin portion is formed by means of a selective oxide film.

5. A method of producing a semiconductor device, comprising the steps of:
an etching stopper formation step that forms an etching stopper on a first surface of the semiconductor substrate; and
a thin portion formation step that forms a recessed portion in the semiconductor substrate and a thin portion having at least one through hole formed therein by etching the semiconductor substrate from a second surface that is opposite the first surface of the semiconductor substrate such that the etching stopper remains.

6. A semiconductor device, comprising:
a semiconductor substrate;
an attachment organic film formed on at least a portion of a surface of the semiconductor substrate;
an inorganic film that is formed on a surface of the semiconductor substrate that is opposite the surface in which the attachment organic film is formed, the inorganic film having a through hole which the attachment organic film cannot pass through;
an organic film that is provided on the surface of the inorganic film such that the inorganic film is interposed between the attachment organic film and the organic film, the organic film unitarily formed with the attachment organic film via the through hole.

7. The semiconductor device set forth in claim 6, wherein:
localized recessed portions are formed in the surface of the semiconductor substrate; and
the attachment organic films are formed by filling the recessed portions with the organic film via the through holes.

8. The semiconductor device set forth in claim 6, wherein the attachment organic films are comprised of portions of the organic film formed on the surface of the semiconductor substrate.

9. The semiconductor device set forth in claim 6, wherein a functional component is formed in the organic film that generates pressure in a direction that can delaminate the organic film from the inorganic film away.

10. The semiconductor device set forth in claim 6, wherein the inorganic film is a metallic film that is applied with a predetermined patterning.

11. A semiconductor device; comprising:
a semiconductor substrate;
an inorganic film that is formed on one main surface of the semiconductor substrate; and
an organic film that is formed on a surface of the inorganic film such that the inorganic film is interposed between the semiconductor substrate and the organic film;
wherein a through hole is formed in the inorganic film such that the through hole passes from the main surface of the inorganic film on the organic film side through to an opposite side of the inorganic film, attachment recessed portions are formed in the semiconductor substrate such that at least one portion of each of the outer peripheries thereof extends outward beyond the through holes; and
the organic film is filled into the through holes and attachment recessed portions.

12. A semiconductor device; comprising:
a semiconductor substrate;
a first organic film that is formed on one main surface of the semiconductor substrate;
an inorganic film that is formed on a side of the first organic film that is opposite the side formed on the main surface of the semiconductor substrate; and
a second organic film that is formed on a surface of the inorganic film such that the inorganic film is interposed between the first organic film and the second organic film;
wherein a through hole is formed in the inorganic film such that the through hole passes from the main surface of the inorganic film on the second organic film side through to an opposite side of the inorganic film, and the second organic film and the first organic film are linked together and unitarily formed via the through holes.
